(19) United States
(12) Patent Application Publication
(10) Pub. No.: US 2013/0140515 A1
(43) Pub. Date: Jun. 6, 2013

(54) NONVOLATILE MEMORY ELEMENT AND METHOD OF MANUFACTURING THE SAME

(71) Applicants: Yoshio Kawashima, Osaka (JP); Takumi Mikawa, Shiga (JP); Ichirou Takahashi, Kyoto (JP)

(72) Inventors: Yoshio Kawashima, Osaka (JP); Takumi Mikawa, Shiga (JP); Ichirou Takahashi, Kyoto (JP)

(21) Appl. No.: 13/810,840

(22) PCT Filed: Feb. 22, 2012
(86) PCT No.: PCT/JP2012/001214

§ 371 Date: Jan. 17, 2013

(30) Foreign Application Priority Data
Feb. 23, 2011 (JP) 2011-037709

(51) Int. Cl. H01L 45/00

(52) U.S. Cl. CPC H01L 45/1608; H01L 45/1253
USPC 257/4; 438/382

(57) ABSTRACT

A method of manufacturing a nonvolatile memory element, the method including: forming a first lower electrode layer, a current steering layer, and a first upper electrode layer; forming a second lower electrode layer, a variable resistance layer, and a second upper electrode layer on the first upper electrode layer; patterning the second upper electrode layer, the variable resistance layer, and the lower electrode layer; patterning the first upper electrode layer, the current steering layer, and first lower electrode layer to form a current steering element, using the second lower electrode layer as a mask by use of etching which is performed on the second lower electrode layer at an etching rate lower than at least etching rates at which the second upper electrode layer and the variable resistance layer are etched; and forming a variable resistance element which has an area smaller than the area of the current steering element.

### TECHNICAL FIELD

The present invention relates to a nonvolatile memory element and a method of manufacturing the nonvolatile memory element, and particularly, to a nonvolatile memory element and a method of manufacturing the nonvolatile memory element which stores data using a material having a resistance value which reversibly changes by application of electric pulses.

### BACKGROUND ART

In recent years, along with the development of digital technology in electronic devices, storage devices have been actively developed which are nonvolatile and have a large capacity for storing data such as music, image, or information. For example, nonvolatile memory elements which use a ferroelectric substance as a capacitive element are being used in many fields.

On the other hand, there are other storage devices which attract attention because the storage devices are easily compatible with usual semiconductor processes and can be miniaturized. For example, nonvolatile memory element which uses a magnetoresistance effect memory element such as a TMR (Tunneling Magnetoresistive) element, or a nonvolatile memory element (hereinafter referred to as a ReRAM) using a variable resistance memory element (variable resistance element) which has a resistance value changeable according to applied electrical pulses and retains the state of the variable resistance element.

For example, U.S. Pat. No. 6,753,561 discloses a cross-point structure as one of the structures which achieve high integration of nonvolatile memory elements. In the nonvolatile memory element in the cross-point structure disclosed in U.S. Pat. No. 6,753,561, a plurality of memory elements each having a variable resistance element are disposed in an array. The variable resistance element is disposed in a via hole at a corresponding one of cross-points of a plurality of first wirings and a plurality of second wirings crossing perpendicular to the first wirings. The variable resistance element is connected in series to an element (a nonlinear element or a current steering element) which has nonlinear current/voltage characteristics. The element having the nonlinear current/voltage characteristics selectively activates a predetermined memory element out of a plurality of memory elements in an array. Specifically, by using an MIM (Metal-Insulator-Metal) diode, for example, as a nonlinear element, the current of the variable resistance element can be controlled in both directions.

Japanese Unexamined Patent Application Publication No. 2004-6777 discloses a structure in which memory storage element (variable resistance element) and control element (current steering element) are arranged adjacent to each other in the horizontal direction unlike the vertical direction as in U.S. Pat. No. 6,753,561. The control device is adapted to the memory storage element which changes its state, and supplies a current to the memory storage element. More specifically, the memory storage element is formed to have a cross-sectional area smaller than the cross-sectional area of the control element, and thus an energy level lower than a certain energy level for causing breakdown of the control element, i.e., a necessary and sufficient amount of current for a memory storage element to change the state as a memory element can be supplied, and the memory storage element is reliably caused to break down (a low resistance change when a memory storage element is an anti fuse). A control tunnel junction region of the control element is adapted to operate to control the state change of the memory storage element. In other words, the ratio of the cross-sectional areas of the control element and the memory storage element serves as a memory storage element for the state change, and on the other hand, the control element continues to operate as a control element for the memory storage element. With the above structure, cost effective memory structure with a large capacity is achieved.

For example, WO 2008/047530 discloses a configuration in which a variable resistance element and a diode are vertically disposed in series, a variable resistance film included in the variable resistance element is formed in a contact hole, and the diode is formed on the contact hole, thereby achieving the effective area of the diode larger than the effective area of the variable resistance element. With the configuration disclosed in WO 2008/047530, the effective area of the diode can be made larger than the effective area of the variable resistance element, and thus the current drive capacity of the diode can be further improved.

### CITATION LIST

### Patent Literature

[PTL 1] U.S. Pat. No. 6,753,561
[PTL 2] Japanese Unexamined Patent Application Publication No. 2004-6777
[PTL 3] WO 2008/047530

### SUMMARY OF INVENTION

### Technical Problem

However, in a nonvolatile memory element which includes a variable resistance element and a current steering element, and needs a large current at the time of resistance change, a new structure for the nonvolatile memory element and a method of manufacturing the structure are desired, the nonvolatile memory element being able to allow a large current for a resistance change to flow therethrough and having a high compatibility with mass production processes.

The present invention has been devised in view of the above-mentioned situation, and it is an object of the invention to provide a nonvolatile memory element and a method of manufacturing the nonvolatile memory element, where in a cross-point nonvolatile memory element including a variable resistance element and a current steering element which are connected in series and which can supply a large current to the nonvolatile memory element and has a high compatibility with mass production processes, the nonvolatile memory element includes the variable resistance element, and the current steering element which can supply a necessary and sufficient amount of current for an initial breakdown of a resistance change, and a resistance change operation, and a nonlinear current steering element which has a high compatibility with mass production processes.

### Solution to Problem

In order to achieve the above-mentioned object, a method of manufacturing of a nonvolatile memory element in an embodiment of the present invention is a method of manufacturing of a nonvolatile memory element having a current steering element and a variable resistance element, the method including: forming a first lower electrode layer on a substrate; forming a current steering layer on the first lower electrode layer; forming a first upper electrode layer on the current steering layer; forming a second lower electrode layer on the first upper electrode layer; forming a variable resistance layer comprising a metal oxide on the second lower electrode layer; forming a second upper electrode layer on the variable resistance layer; forming a mask on the second upper electrode layer, and patterning the second upper electrode layer, the variable resistance layer, and the second lower electrode layer; and forming the current steering element including the first upper electrode layer, the current steering layer, and the first upper electrode layer by patterning layers lower than the second lower electrode layer by use of etching which is performed on the second lower electrode layer at an etching rate lower than at least etching rates at which the second upper electrode layer and the variable resistance layer are respectively etched, and forming the variable resistance element including the second upper electrode layer, the variable resistance layer, and the second upper electrode layer, the second upper electrode layer and the variable resistance layer each having an area which is reduced to cause part of an upper surface of the second lower electrode layer to be exposed, the area being as seen in a direction perpendicular to a major surface of the substrate.

In order to achieve the above-mentioned object, a method of manufacturing of a nonvolatile memory element in an embodiment of the present invention is a method of manufacturing a nonvolatile memory element having a current steering element and a variable resistance element, the method including: forming a first lower electrode layer on a substrate; forming a current steering layer on the first lower electrode layer; forming a first upper electrode layer on the current steering layer; forming a second lower electrode layer on the first upper electrode layer; forming a variable resistance layer comprising a metal oxide on the second lower electrode layer; forming a second upper electrode layer on the variable resistance layer; forming the variable resistance element including the second lower electrode layer, the variable resistance layer, and the second upper electrode layer by forming a first mask on the second upper electrode layer and patterning the second lower electrode layer, the variable resistance layer, and the second upper electrode layer; forming an insulating layer which covers the first upper electrode layer and the variable resistance element; forming a sidewall including an insulating layer on lateral surfaces of the second lower electrode layer, the variable resistance layer, and the second upper electrode layer by etching the insulating layer with an anisotropic etching method; and forming the current steering element including the first lower electrode layer, the current steering layer, and the first upper electrode layer by patterning the first lower electrode layer, the current steering layer, and the first upper electrode layer using an region surrounded by the sidewall and the first mask or the second upper electrode layer as a second mask.

In order to achieve the above-mentioned object, a method of manufacturing of a nonvolatile memory element in an embodiment of the present invention is a method of manufacturing a nonvolatile memory element having a current steering element and a variable resistance element, the method including: forming a first lower electrode layer on a substrate; forming a current steering layer on the first lower electrode layer; forming a first upper electrode layer on the current steering layer; forming a second lower electrode layer on the first upper electrode layer; forming a variable resistance layer comprising a metal oxide on the second lower electrode layer; forming a second upper electrode layer on the variable resistance layer; forming the variable resistance element including the second lower electrode layer, the variable resistance layer, and the second upper electrode layer by forming a first mask and patterning at least the variable resistance layer and the second upper electrode layer; forming a second mask which is larger than the first mask and covers at least the first mask, the variable resistance layer, and the second upper electrode layer; and forming the current steering element including the first lower electrode layer, the current steering layer, and the first upper electrode layer by patterning the first lower electrode layer, the current steering layer, and the first upper electrode layer using the formed second mask.

A nonvolatile memory element in an embodiment of the present invention includes a variable resistance element and a current steering element which are connected in series, the current steering element including: a first lower electrode layer formed on a substrate; a current steering layer formed on the first lower electrode layer; and a first upper electrode layer formed on the current steering layer, the variable resistance element including: a second lower electrode layer formed on the first upper electrode layer; a variable resistance layer comprising a metal oxide and formed on the second lower electrode layer; a second upper electrode layer formed on the variable resistance layer, wherein a width of the current steering element in a direction parallel to each layer included in the current steering element is greater than a width of the variable resistance layer in a direction parallel to a layer included in at least the variable resistance layer in the variable resistance element, and the current steering element has a step surface which is parallel to the substrate and is a surface having an area according to at least a width difference between the variable resistance layer in the variable resistance element and the current steering element.

### Advantageous Effects of Invention

The present invention achieves a nonvolatile memory element and a method of manufacturing the nonvolatile memory element which has high compatibility with the existing semiconductor processes and can supply a large current to a variable resistance element.

### BRIEF DESCRIPTION OF DRAWINGS

FIG. 1 is a plan view illustrating a configuration example of a memory cell array in an embodiment of the present invention.

FIG. 2A is a cross-sectional view illustrating the configuration of a nonvolatile memory device having a nonvolatile memory element according to Embodiment 1 of the present invention.

FIG. 2B is a cross-sectional view illustrating the configuration of a nonvolatile memory device having a nonvolatile memory element according to Embodiment 1 of the present invention.

FIG. 3 is a cross-sectional view of a variable resistance element and a current steering element which are included in the nonvolatile memory element according to Embodiment 1 of the present invention.

FIG. 4 is a cross-sectional view of a variable resistance element and a current steering element which are included in a nonvolatile memory element according to a comparative example.

FIG. 5A is a cross-sectional view illustrating a method of manufacturing the nonvolatile memory device having the nonvolatile memory element according to Embodiment 1 of the present invention.

FIG. 5B is a cross-sectional view illustrating the method of manufacturing the nonvolatile memory device having the nonvolatile memory element according to Embodiment 1 of the present invention.

FIG. 5C is a cross-sectional view illustrating the method of manufacturing the nonvolatile memory device having the nonvolatile memory element according to Embodiment 1 of the present invention.

FIG. 5D is a cross-sectional view illustrating the method of manufacturing the nonvolatile memory device having the nonvolatile memory element according to Embodiment 1 of the present invention.

FIG. 5E is a cross-sectional view illustrating the method of manufacturing the nonvolatile memory device having the nonvolatile memory element according to Embodiment 1 of the present invention.

FIG. 5F is a cross-sectional view illustrating the method of manufacturing the nonvolatile memory device having the nonvolatile memory element according to Embodiment 1 of the present invention.

FIG. 5G is a cross-sectional view illustrating the method of manufacturing the nonvolatile memory device having the nonvolatile memory element according to Embodiment 1 of the present invention.

FIG. 5H is a cross-sectional view illustrating the method of manufacturing the nonvolatile memory device having the nonvolatile memory element according to Embodiment 1 of the present invention.

FIG. 5I is a cross-sectional view illustrating the method of manufacturing the nonvolatile memory device having the nonvolatile memory element according to Embodiment 1 of the present invention.

FIG. 5J is a cross-sectional view illustrating the method of manufacturing the nonvolatile memory device having the nonvolatile memory element according to Embodiment 1 of the present invention.

FIG. 5K is a cross-sectional view illustrating the method of manufacturing the nonvolatile memory device having the nonvolatile memory element according to Embodiment 1 of the present invention.

FIG. 6A is a cross-sectional view illustrating a configuration example of a nonvolatile memory device having a nonvolatile memory element according to Embodiment 2 of the present invention.

FIG. 6B is a cross-sectional view illustrating a configuration example of the nonvolatile memory device having the nonvolatile memory element according to Embodiment 2 of the present invention.

FIG. 7 is a cross-sectional view of a variable resistance element and a current steering element which are included in a nonvolatile memory element according to Embodiment 2 of the present invention.

FIG. 8A is a cross-sectional view illustrating a method of manufacturing the nonvolatile memory device having the nonvolatile memory element according to Embodiment 2 of the present invention.

FIG. 8B is a cross-sectional view illustrating the method of manufacturing the nonvolatile memory device having the nonvolatile memory element according to Embodiment 2 of the present invention.

FIG. 8C is a cross-sectional view illustrating the method of manufacturing the nonvolatile memory device having the nonvolatile memory element according to Embodiment 2 of the present invention.

FIG. 8D is a cross-sectional view illustrating the method of manufacturing the nonvolatile memory device having the nonvolatile memory element according to Embodiment 2 of the present invention.

FIG. 8E is a cross-sectional view illustrating the method of manufacturing the nonvolatile memory device having the nonvolatile memory element according to Embodiment 2 of the present invention.

FIG. 8F is a cross-sectional view illustrating the method of manufacturing the nonvolatile memory device having the nonvolatile memory element according to Embodiment 2 of the present invention.

FIG. 8G is a cross-sectional view illustrating the method of manufacturing the nonvolatile memory device having the nonvolatile memory element according to Embodiment 2 of the present invention.

FIG. 8H is a cross-sectional view illustrating the method of manufacturing the nonvolatile memory device having the nonvolatile memory element according to Embodiment 2 of the present invention.

FIG. 9A is a cross-sectional view illustrating a configuration example of a nonvolatile memory device having a nonvolatile memory element according to Embodiment 3 of the present invention.

FIG. 9B is a cross-sectional view illustrating a configuration example of the nonvolatile memory device having the nonvolatile memory element according to Embodiment 3 of the present invention.

FIG. 10 is a cross-sectional view of a variable resistance element and a current steering element which are included in the nonvolatile memory element according to Embodiment 3 of the present invention.

FIG. 11A is a cross-sectional view illustrating a method of manufacturing the nonvolatile memory device having the nonvolatile memory element according to Embodiment 3 of the present invention.

FIG. 11B is a cross-sectional view illustrating the method of manufacturing the nonvolatile memory device having the nonvolatile memory element according to Embodiment 3 of the present invention.

FIG. 11C is a cross-sectional view illustrating the method of manufacturing the nonvolatile memory device having the nonvolatile memory element according to Embodiment 3 of the present invention.

FIG. 11D is a cross-sectional view illustrating the method of manufacturing the nonvolatile memory device having the nonvolatile memory element according to Embodiment 3 of the present invention.

FIG. 11E is a cross-sectional view illustrating the method of manufacturing the nonvolatile memory device having the nonvolatile memory element according to Embodiment 3 of the present invention.

FIG. 11F is a cross-sectional view illustrating the method of manufacturing the nonvolatile memory device having the nonvolatile memory element according to Embodiment 3 of the present invention.

FIG. 11G is a cross-sectional view illustrating the method of manufacturing the nonvolatile memory device having the nonvolatile memory element according to Embodiment 3 of the present invention.

FIG. 11H is a cross-sectional view illustrating the method of manufacturing the nonvolatile memory device having the nonvolatile memory element according to Embodiment 3 of the present invention.

FIG. 12 is a graph illustrating the dependence of an initial breakdown current on the area of a variable resistance element, and the dependence of a breakdown current on the area of a current steering element, the variable resistance element and the current steering element being included in the nonvolatile memory element according to Embodiment 1 of the present invention.

### DESCRIPTION OF EMBODIMENTS

First, before the embodiments of the present invention are described, what the inventors have discussed will be described for the sake of facilitating the understanding of the below-described embodiments. The above description is provided as an aid for understanding the below-described embodiments, and the present invention is not limited by the description.

In some cases, in order to cause a variable resistance element to operate, initialization operation for resistance change (initial breakdown) is necessary to change the variable resistance element from a very high resistance state (initial state) immediately after manufacture to a state in which the variable resistance element can stably change its resistance. The initial breakdown is performed in order to cause a variable resistance layer immediately after manufacture to change from an initial state thereof to a state which allows a resistance change operation by applying a voltage or current higher than a predetermined threshold voltage or threshold current to the variable resistance layer.

For example, when a variable resistance layer includes two layers of a low oxygen-deficient layer (high resistance layer) and a high oxygen-deficient layer (low resistance layer) which each comprise an oxygen-deficient transition metal oxide, the initial breakdown is performed in order to form a low resistance region (conductive path or a filament) using part of a high resistance layer, and in the formed filament region, resistance change phenomenon can be caused to occur stably.

For example, when an MIM diode is used as a current steering element in a nonvolatile memory element in which a variable resistance element and a current steering element are connected in series, an insulating film having a thickness in the order of several nm is typically used to cause the MIM diode to operate with a low voltage. The current steering element may undergo dielectric breakdown when the initial breakdown of the variable resistance element, or the current density necessary for a resistance change operation is high. In other words, when the initial breakdown of the variable resistance element, or the current density necessary for a resistance change operation is high, the insulation property of the insulating film of the current steering element may be impaired, and thus nonlinear characteristics of the current steering element may be impaired.

On the contrary, by adopting a structure in which the cross section of the current steering element is larger than that of the variable resistance element in order to improve the current driving capability of the current steering element, a sufficient amount of current can be supplied to the variable resistance element. However, when such a structure is constructed by a conventional manufacturing method, the method involves a complicated process including a plurality of steps, and thus a nonvolatile memory element which can be produced by a simpler manufacturing method is desired. Specifically, a structure in which a current steering element and a variable resistance element are arranged in series perpendicularly to a substrate, or a structure in which a plurality of nonvolatile memory elements are horizontally disposed adjacent to each other is desirably manufactured in a simpler manner, so that the cross section of the current steering element is larger than that of the variable resistance element. The above manufacturing method is desired to be compatible with miniaturization processes and to have reduced process damage to the variable resistance film or the like.

The inventors have studied a nonvolatile memory element including a current steering element which can stably supply a large current to a variable resistance element, and a method of manufacturing the nonvolatile memory element. As a result of the study, the inventors have devised a nonvolatile memory element (nonvolatile memory cell) which has compatibility with miniaturization processes at the present and in the future technology, and is suitable for mass production processes.

A method of manufacturing a nonvolatile memory element in an embodiment of the present invention is a method of manufacturing of a nonvolatile memory element having a current steering element and a variable resistance element, the method including: forming a first lower electrode layer on a substrate; forming a current steering layer on the first lower electrode layer; forming a first upper electrode layer on the current steering layer; forming a second lower electrode layer on the first upper electrode layer; forming a variable resistance layer comprising a metal oxide on the second lower electrode layer; forming a second upper electrode layer on the variable resistance layer; forming a mask on the second upper electrode layer, and patterning the second upper electrode layer, the variable resistance layer, and the second lower electrode layer; and forming the current steering element including the first upper electrode layer, the current steering layer, and the first upper electrode layer by patterning layers lower than the second lower electrode layer by use of etching which is performed on the second lower electrode layer at an etching rate lower than at least etching rates at which the second upper electrode layer and the variable resistance layer are respectively etched, and forming the variable resistance element including the second upper electrode layer, the variable resistance layer, and the second upper electrode layer, the second upper electrode layer and the variable resistance layer each having an area which is reduced to cause part of an upper surface of the second lower electrode layer to be exposed, the area being as seen in a direction perpendicular to a major surface of the substrate.

Thus, the second upper electrode layer and the variable resistance layer can be patterned so as to have an area smaller than the area of the current steering element when viewed in a direction perpendicular to the major surface of the substrate.

Here, in the process of forming the variable resistance element, the mask has a tapered shape.

In this manner, with the mask having a tapered shape, the second upper electrode layer and the variable resistance layer can be efficiently patterned so as to have an area smaller than the area of the current steering element when viewed in a direction perpendicular to the major surface of the substrate.

Here, the first upper electrode layer, the current steering layer, and the first lower electrode layer may be arranged below the second lower electrode layer.

The second lower electrode layer and the first upper electrode layer may be a common layer which comprises the same material, and the step of forming the first upper electrode layer, and the step of forming the second lower electrode layer may be the same step. The current steering layer and the first lower electrode layer may be arranged below the second lower electrode layer.

That is to say, the second lower electrode layer and the first upper electrode layer may be a common component.

The second lower electrode layer preferably comprises precious metal including iridium, platinum, and palladium.

With the above configuration, not only the effective area of the variable resistance element or at least the effective area of the current steering element can be made larger than the area of operation of the variable resistance element using a single mask pattern without adding a particular step, but also the variable resistance element and the current steering element can be formed in series in symmetrical concentric circular shapes when viewed from above the upper surface of the substrate. Consequently, it is possible to easily manufacture a nonvolatile memory device in which even when a current steering element in a conventional configuration is used, a larger amount of current can flow without causing the current steering element to break down, and a necessary and sufficient amount of current for operating the variable resistance element can flow through the variable resistance element.

In the present invention, the operation of a variable resistance element (resistance change operation) includes a normal resistance change operation, and an initial operation (initial breakdown) to be performed to cause a resistance change operation.

Because the variable resistance element can be produced with a single mask pattern, the number of masks can be decreased, and the costs can be reduced.

In addition, a current steering element is formed by causing the second lower electrode layer of the variable resistance element to serve as a mask, and the variable resistance element can be formed by shrinking a variable resistance layer included in the variable resistance element, and the end face (the width of the layers in the direction parallel to the layers) of the second upper electrode. Furthermore, because the effective area of the variable resistance element can be adjusted with the etching rate at the time of etching (degree of shrinking), the effect is achieved that a fine pattern, which is difficult to be implemented with a mask pattern, can be formed.

Therefore, the nonvolatile memory device can be manufactured by a semiconductor process using the conventional CMOS process or the like, and thus a specific and special semiconductor process does not need to be used in manufacturing the variable resistance element and the current steering element. Two elements having different sizes can be formed with a single mask pattern, and mask alignment accuracy is not necessary. Consequently, the nonvolatile memory device can be manufactured with improved compatibility with advanced semiconductor miniaturization processes.

Here, the variable resistance layer may be a stacked structure including a first oxygen-deficient transition metal oxide layer, and a second transition metal oxide layer having a degree of oxygen deficiency lower than the degree of oxygen deficiency of the first oxygen-deficient transition metal oxide layer, and the second transition metal oxide layer may be in contact with the second lower electrode layer.

The resistance value of the second transition metal oxide layer may be higher than the resistance value of the first transition metal oxide layer.

The standard electrode potential of the first transition metal comprised in the first transition metal oxide layer may be higher than the standard electrode potential of the first transition metal comprised in the second transition metal oxide layer.

The variable resistance layer may comprise a tantalum oxide TaOₓ (0<x<2.5), a hafnium oxide HfOₓ (0<x<2.0), or a zirconium oxide ZrOₓ (0<x<2.0).

Consequently, a nonvolatile memory device which has reversibly stable rewriting characteristics and favorable retention characteristics in addition to high-speed operation can be achieved.

A method of manufacturing a nonvolatile memory device in an embodiment of the present invention is a method of manufacturing a nonvolatile memory element having a current steering element and a variable resistance element, the method including: forming a first lower electrode layer on a substrate; forming a current steering layer on the first lower electrode layer; forming a first upper electrode layer on the current steering layer; forming a second lower electrode layer on the first upper electrode layer; forming a variable resistance layer comprising a metal oxide on the second lower electrode layer; forming a second upper electrode layer on the variable resistance layer; forming the variable resistance element including the second lower electrode layer, the variable resistance layer, and the second upper electrode layer by forming a first mask on the second upper electrode layer and patterning the second lower electrode layer, the variable resistance layer, and the second upper electrode layer; forming an insulating layer which covers the first upper electrode layer and the variable resistance element; forming a sidewall including an insulating layer on lateral surfaces of the second lower electrode layer, the variable resistance layer, and the second upper electrode layer by etching the insulating layer with an anisotropic etching method; and forming the current steering element including the first lower electrode layer, the current steering layer, and the first upper electrode layer by patterning the first lower electrode layer, the current steering layer, and the first upper electrode layer using an region surrounded by the sidewall and the first mask or the second upper electrode layer as a second mask.

With the above configuration, not only the effective area of the current steering element can be made larger than the area of operation of the variable resistance element using a single mask pattern without adding a particular step, but also the variable resistance element and the current steering element can be formed in series in symmetrical concentric circular shape when viewed from above the upper surface of the substrate. Consequently, it is possible to easily manufacture a nonvolatile memory device in which even when a current steering element in a conventional configuration is used, a larger amount of current can flow without causing the current steering element to break down, and a necessary and sufficient amount of current for operating the variable resistance element can flow through the variable resistance element.

Because the nonvolatile memory device is compatible with advanced semiconductor miniaturization processes, the nonvolatile memory device can be manufactured by a semiconductor process using the conventional CMOS process or the like. This is because a specific and special semiconductor process does not need to be used in manufacturing the variable resistance element and the current steering element, two elements having different sizes can be formed with a single mask pattern, and thus mask alignment accuracy is not necessary.

In addition, the elements can be manufactured with a single mask pattern, thus the number of masks can be decreased, and the costs can be reduced.

Here, the second lower electrode layer and the first upper electrode layer may be a common layer which comprises the same material, and the step of forming the first upper electrode layer, and the step of forming the second lower electrode layer on the first upper electrode layer may be the same step. In the step of forming the variable resistance element, part of the common layer may be patterned, and in the step of forming the sidewall, the sidewall may be formed on the lateral surface of the patterned part of the common layer, and the lateral surfaces of the variable resistance layer and the second upper electrode layer.

At least one of the second upper electrode layer and the second lower electrode layer may comprise precious metal including iridium, platinum, and palladium.

Consequently, a nonvolatile memory device which has reversibly stable rewriting characteristics and favorable retention characteristics in addition to high-speed operation can be achieved.

The variable resistance layer may be a stacked structure including a first oxygen-deficient transition metal oxide layer, and a second transition metal oxide layer having a degree of oxygen deficiency lower than the degree of oxygen deficiency of the first oxygen-deficient transition metal oxide layer, and the second transition metal oxide layer may be in contact with the second lower electrode layer.

The resistance value of the second transition metal oxide layer may be higher than the resistance value of the first transition metal oxide layer.

The standard electrode potential of the first transition metal comprised in the first transition metal oxide layer may be higher than the standard electrode potential of the first transition metal comprised in the second transition metal oxide layer.

The variable resistance layer may comprise a tantalum oxide TaOₓ (0<x<2.5), a hafnium oxide HfOₓ (0<x<2.0), or a zirconium oxide ZrOₓ (0<x<2.0).

Thus, a variable resistance element which has reversibly stable rewriting characteristics, and uses resistance change phenomenon can be obtained.

A method of manufacturing a nonvolatile memory device in an embodiment of the present invention is a method of manufacturing a nonvolatile memory element having a current steering element and a variable resistance element, the method including: forming a first lower electrode layer on a substrate; forming a current steering layer on the first lower electrode layer; forming a first upper electrode layer on the current steering layer; forming a second lower electrode layer on the first upper electrode layer; forming a variable resistance layer comprising a metal oxide on the second lower electrode layer; forming a second upper electrode layer on the variable resistance layer; forming the variable resistance element including the second lower electrode layer, the variable resistance layer, and the second upper electrode layer by forming a first mask and patterning at least the variable resistance layer and the second upper electrode layer; forming a second mask which is larger than the first mask and covers at least the first mask, the variable resistance layer, and the second upper electrode layer; and forming the current steering element including the first lower electrode layer, the current steering layer, and the first upper electrode layer by patterning the first lower electrode layer, the current steering layer, and the first upper electrode layer using the formed second mask.

Thus, the effective area of at least the current steering element can be made larger than the area of operation of the variable resistance element only by the step of patterning each element (the step of forming each element by dry etching using two mask patterns) after the step of depositing respective electrodes, variable resistance layers, and current steering layers which are included in the variable resistance element and the current steering element. Consequently, the effect is achieved that it is possible to easily manufacture a nonvolatile memory device in which even when a current steering element in a conventional configuration is used, a larger amount of current can flow without causing the current steering element to break down, and a necessary and sufficient amount of current for operating the variable resistance element can flow through the variable resistance element.

Therefore, the nonvolatile memory device can be manufactured by a semiconductor process using the conventional CMOS process or the like, and thus a specific and special semiconductor process does not need to be used in manufacturing the variable resistance element and the current steering element. Consequently, the variable resistance element can be manufactured with improved compatibility with advanced semiconductor miniaturization processes.

Here, the second lower electrode layer and the first upper electrode layer may be a common layer which comprises the same material, and the step of forming the first upper electrode layer, and the step of forming the second lower electrode layer on the first upper electrode layer may be the same step.

At least one of the second upper electrode layer and the second lower electrode layer may comprise iridium, platinum, or palladium.

Consequently, a nonvolatile memory device which has reversibly stable rewriting characteristics and favorable retention characteristics in addition to high-speed operation can be achieved.

Here, the variable resistance layer may be a stacked structure including a first oxygen-deficient transition metal oxide layer, and a second transition metal oxide layer having a degree of oxygen deficiency lower than the degree of oxygen deficiency of the first oxygen-deficient transition metal oxide layer, and the second transition metal oxide layer may be in contact with the second lower electrode layer.

The resistance value of the second transition metal oxide layer may be higher than the resistance value of the first transition metal oxide layer.

The standard electrode potential of the first transition metal comprised in the first transition metal oxide layer may be higher than the standard electrode potential of the first transition metal comprised in the second transition metal oxide layer.

The metal oxide is a tantalum oxide TaOₓ (0<x<2.5), a hafnium oxide HfOₓ (0<x<2.0), or a zirconium oxide ZrOₓ (0<x<2.0).

Thus, a variable resistance element which has reversibly stable rewriting characteristics, and uses resistance change phenomenon can be obtained.

The variable resistance element and the current steering element are patterned after all of the upper and lower electrode layers and the variable resistance layer included in the variable resistance element, and the upper and lower electrode layers and the current steering layer included in the current steering element are formed by the method of manufacturing a nonvolatile memory device in the above-described embodiments. For this reason, a connecting surface between layers has less process damage (for example, roughness on the surface of a film, and a variation in the film thickness due to CMP processing on the connecting surface in the step of forming a variable resistance element in a contact hole), and thus a stable connecting surface (interface state) can be obtained. Consequently, a high-quality nonvolatile memory device which provides stable operation with a less variation in operation can be manufactured.

The current steering element may be a component in the conventional configuration, i.e., an MIM (Metal-Insulator-Metal) diode, an MSM (Metal-Semiconductor-Metal) diode, or Schottky diode. Because the effective area of the current steering element can be made larger than the area of operation of the variable resistance element, even when the breakdown current density of the current steering element is lower than or equal to the current density necessary for a resistance change operation of the variable resistance element, a larger amount of current can flow using the current steering element in the aforementioned conventional configuration, and thus a necessary and sufficient amount of current for operating the variable resistance element can flow through the variable resistance element.

A nonvolatile memory device in an embodiment of the present invention includes a variable resistance element and a current steering element which are connected in series, the current steering element including: a first lower electrode layer formed on a substrate; a current steering layer formed on the first lower electrode layer; and a first upper electrode layer formed on the current steering layer, the variable resistance element including: a second lower electrode layer formed on the first upper electrode layer; a variable resistance layer comprising a metal oxide and formed on the second lower electrode layer; a second upper electrode layer formed on the variable resistance layer, wherein a width of the current steering element in a direction parallel to each layer included in the current steering element is greater than a width of the variable resistance layer in a direction parallel to a layer included in at least the variable resistance layer in the variable resistance element, and the current steering element has a step surface which is parallel to the substrate and is a surface having an area according to at least a width difference between the variable resistance layer in the variable resistance element and the current steering element.

With this configuration, the effective area of the current steering element is larger than the area of operation of the variable resistance element, and therefore, even when a current steering element in the conventional configuration is used, a larger amount of current can flow without causing the current steering element to break down, and a necessary and sufficient amount of current for operating the variable resistance element can flow through the variable resistance element.

Here, the second lower electrode layer and the first upper electrode layer may comprise the same material.

The variable resistance element may have a sidewall including an insulating layer on the lateral surfaces of the second lower electrode layer, the variable resistance layer, and the second upper electrode layer.

At least one of the second upper electrode layer and the second lower electrode layer may comprise iridium, platinum, or palladium.

The metal oxide may comprise a tantalum oxide TaOₓ (0<x<2.5), a hafnium oxide HfOₓ (0<x<2.0), or a zirconium oxide ZrOₓ (0<x<2.0).

In this manner, according to the various embodiments of the present invention, a nonvolatile memory device and a method of manufacturing the nonvolatile memory device can be implemented, the nonvolatile memory device having improved compatibility with the existing semiconductor processes, and including a current steering element which can supply a necessary and sufficient amount of current for the variable resistance element, a resistance change operation, and an initial breakdown. Specifically, a nonvolatile memory device, in which the effective area of the current steering element is larger than the area of operation of the variable resistance element, can be manufactured only by the step of patterning each element after the step of depositing respective electrodes, variable resistance layers, and current steering layers which are included in the variable resistance element and the current steering element. Consequently, the effect is achieved that a nonvolatile memory device and a method of manufacturing the nonvolatile memory device, which allows easy miniaturization and is stable, can be implemented.

Hereinafter, a nonvolatile memory device and a method of manufacturing the nonvolatile memory device according to an embodiment of the present invention will be described with reference to the drawings. In the drawings, description of components with the same reference symbols may be omitted. The drawings illustrate each component schematically for the sake of facilitating understanding, and the shape of each component is not accurately illustrated, and the number of components is adjusted for easy illustration. Each of the embodiments described below is a preferable example of the present invention. The numerical values, shapes, materials, components, arrangement positions and connection topologies of the components, steps, the order of the steps which are shown in the following embodiments are examples, and not intended to limit the present invention. Therefore, the components out of the components in following embodiments, which are not described in the independent claim which provides the most generic concept of the present invention are described as optional components for a more preferable embodiment.

### Embodiment 1

The configuration and method of manufacturing a nonvolatile memory device having a nonvolatile memory element according to Embodiment 1 of the present invention will be described.

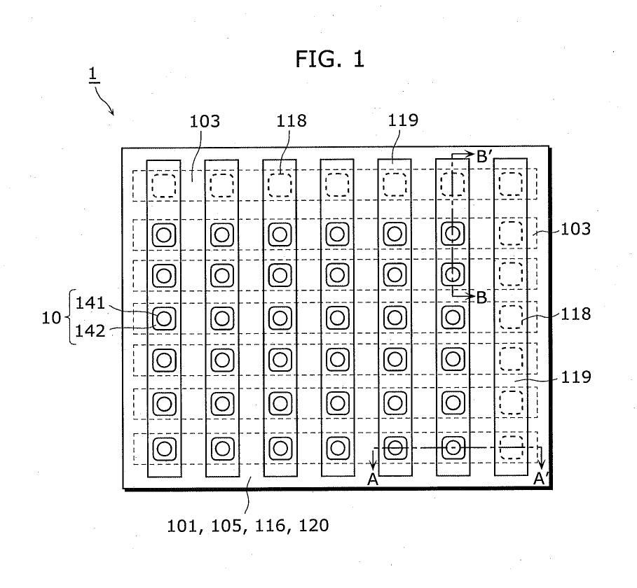

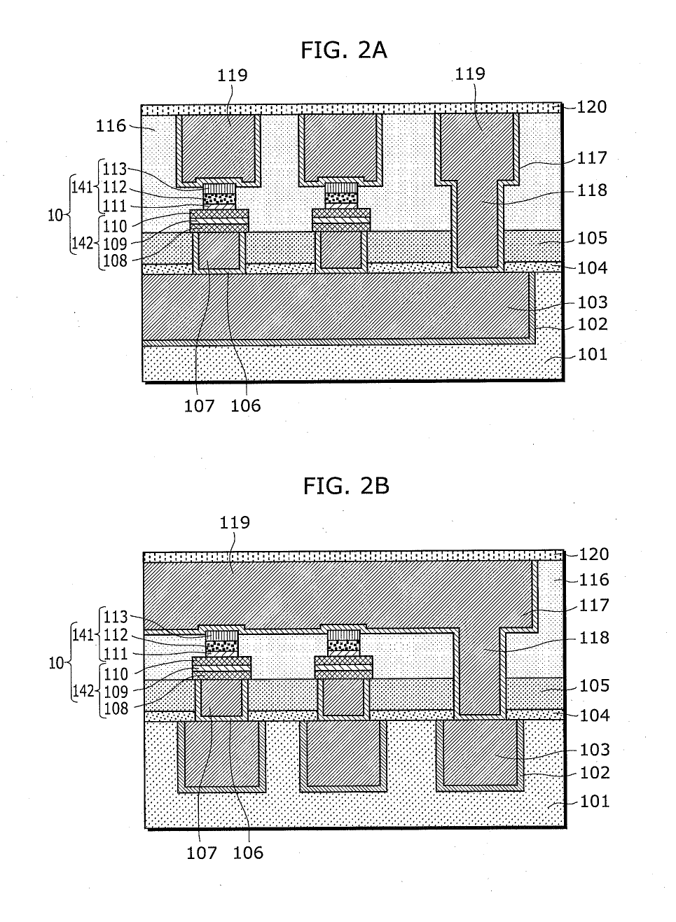

FIG. 1 is a plan view illustrating a configuration example of a nonvolatile memory element (memory cell) array 1 which is a matrix of nonvolatile memory elements 10 according to Embodiment 1 of the present invention. FIGS. 2A and 2B are each a cross-sectional view illustrating a configuration example of the nonvolatile memory element 10 according to Embodiment 1 of the present invention. FIG. 2A is a cross-sectional view, as seen in an arrow direction, taken along the chain line indicated by A-A′ in FIG. 1. FIG. 2B is a cross-sectional view, as seen in an arrow direction, taken along the chain line indicated by B-B′ in FIG. 1. As illustrated in FIG. 1, the memory cell array 1 in which the nonvolatile memory elements 10 as memory cells are integrated.

The memory cell array 1 illustrated in FIG. 1 includes a plurality of first wirings 103; a plurality of second wirings 119; and nonvolatile memory elements 10, each of which includes a variable resistance element 141 and a current steering element 142, and is disposed at corresponding one of the cross points of the first wirings 103 and the second wirings 119.

The first wirings 103 are formed on a substrate in which the transistors or the like are formed. The first wirings 103 are disposed in parallel with each other in a stripe pattern. The second wirings 119 are disposed in parallel with each other in a stripe pattern. Hereinafter, description is provided under the assumption that the first wirings 103 and the second wirings 119 are perpendicular, however, the first and second wirings 103, 119 are not necessarily perpendicular and may be arranged so as to cross each other. The above condition applies to the below-described second embodiment and third embodiment. A stacked structure including the variable resistance element 141 and the current steering element 142 is formed at each of the cross points of the first wirings 103 and the second wirings 119.

Hereinafter, the specific configuration of the nonvolatile memory element 10 will be described.

As illustrated in FIGS. 2A and 2B, the memory cell array 1 includes a first interlayer insulating layer 101, a first barrier metal layer 102, a first wiring 103, a first liner layer 104, a second interlayer insulating layer 105, a second barrier metal layer 106, a plug 107, a variable resistance element 141, a current steering element 142, a third interlayer insulating layer 116, a third barrier metal layer 117, a drawing contact 118, second wiring 119, and a second liner layer 120. However, the memory cell array 1 may adopt other configuration in a range without departing from the gist of Embodiment 1 of the present invention.

The first interlayer insulating layer 101 is formed on a substrate (not illustrated), in which transistors or the like are formed. The first interlayer insulating layer 101 comprises, for example, a silicon oxide.

The first barrier metal layer 102 is formed in a wiring groove which is formed so to embed the first wiring 103 into the first interlayer insulating layer 101. The first barrier metal layer 102 is formed with tantalum nitride having a thickness of 5 to 40 nm, and tantalum having a thickness of 5 to 40 nm.

The first wiring 103 comprises copper and is formed in the first interlayer insulating layer 101. Specifically, the first wiring 103 is formed on the first barrier metal layer 102 which is formed in the wiring groove of the first interlayer insulating layer 101, so that the wiring groove is totally filled with the first wiring 103.

The first liner layer 104 is formed on the first interlayer insulating layer 101 which includes the first wiring 103. The first liner layer 104 comprises, for example, silicon nitride having a thickness of 30 to 200 nm.

The second interlayer insulating layer 105 is formed on the first liner layer 104, and comprises, for example, a silicon oxide having a thickness of 100 to 500 nm.

Here, the first liner layer 104 and the second interlayer insulating layer 105 each have a drawing contact 118 therein.

The second barrier metal layer 106 is formed in the first liner layer 104 and the second interlayer insulating layer 105, and, specifically, is formed in a contact hole which is formed in the first liner layer 104 and the second interlayer insulating layer 105. The second barrier metal layer 106 includes, for example, nitride having a thickness of 5 to 40 nm and tantalum having a thickness of 5 to 40 nm which are deposited.

The plug 107 is formed in a contact hole in the first liner layer 104 and the second interlayer insulating layer 105, and is electrically connected to the first wiring 103. Specifically, the plug 107 is formed on the second barrier metal layer 106 in the contact hole formed in the first liner layer 104 and the second interlayer insulating layer 105, and is electrically connected to the first wiring 103. The plug 107 is formed with a thickness of 50 to 200 nm, for example.

The current steering element 142 is formed on the second interlayer insulating layer 105, and is electrically and physically connected to the plug 107. The current steering element 142 includes the first lower electrode layer 108, the current steering layer 109, and the first upper electrode layer 110.

The first lower electrode layer 108 is formed on a substrate (specifically, on the second interlayer insulating layer 105), and comprises, for example, tantalum nitride. The current steering layer 109 is formed on the first lower electrode layer 108, and comprises, for example, nitrogen-deficient silicon nitride

The first upper electrode layer 110 is formed on the current steering layer 109, and comprises, for example, tantalum nitride.

Here, the nitrogen-deficient silicon nitride is a silicon nitride such that when the composition of the silicon nitride is expressed as SiN_{Z} (0<z), the number z of nitrogen N is smaller than that in stoichiometrically stable state. Because Si₃N₄ has a stoichiometrically stable state, a silicon nitride is referred to as nitrogen-deficient silicon nitride when 0<z<1.33. The nitrogen-deficient silicon nitride exhibits semiconductor characteristics. When nitrogen-deficient silicon nitride is used in the current steering layer 109, and tantalum nitride is used as an electrode material of the first lower electrode layer 108 and the first upper electrode layer 110, an MSM diode, which allows a sufficient voltage/current for a resistance change to be turned ON/OFF, can be formed in a range of 0<z≦0.85. For example, an ON-state current density of 10000 A/cm² or higher, and an ON/OFF ratio of 10 fold or greater can be achieved. In general, an MSM diode allows an ON-state current having a current density higher than that of an MIM diode to flow through the MSM diode.

The work function of tantalum nitride is 4.6 eV, which is sufficiently higher than 3.8 eV, the electron affinity of silicon, and thus a Schottky barrier is formed at the interface between the first lower electrode layer 108 and the current steering layer 109, and the interface between the current steering layer 109 and the first upper electrode layer 110. High melting point metal such as tantalum, and a nitride of the metal excel in heat resistance, and exhibits stable characteristics against application of a current having a high current density. Because of the above reasons, the electrode material comprised in the MSM diode is preferably a tantalum, a tantalum nitride, a titanium, a titanium nitride, a tungsten, or a tungsten nitride.

The current steering element 142 is formed as described above.

The variable resistance element 141 is formed to be connected in series on the current steering element 142. The variable resistance element 141 includes the second lower electrode layer 111, the variable resistance layer 112, and the second upper electrode layer 113.

The variable resistance layer 112 is formed on the second lower electrode layer 111, and comprises a metal oxide. The variable resistance layer 112 comprises, for example, an oxygen-deficient transition metal oxide.

Here, the oxygen-deficient transition metal oxide is a metal oxide such that when the transition metal oxide is expressed as MOₓ where M is transition metal and O is oxygen, the number x of oxygen O is smaller than that in stoichiometrically stable state (normally insulating material in this case). An oxide using various types of transition metals may be used for the oxygen-deficient transition metal oxide. However, a variable resistance element, which has reversibly stable rewriting characteristics, and uses resistance change phenomenon, can be obtained by using a variable resistance layer comprising, for example, a tantalum oxide (TaOₓ, 0<x<2.5) or a hafnium oxide (HfOₓ, 0<x<2.0). The assignee has already filed a patent application as related application, and the tantalum oxide and the hafnium oxide are described in detail in WO 2008/059701 and WO 2009/050861, respectively.

Although the variable resistance layer 112 is described by way of example in which the variable resistance layer 112 is formed with a single layer, however, the variable resistance layer 112 is not limited to the above. That is to say, in the variable resistance layer 112, the oxygen-deficient transition metal oxide may include at least two layers of a low oxygen-deficient layer and a high oxygen-deficient layer. Here, “degree of oxygen deficiency” in a transition metal oxide means the ratio of insufficient oxygen to the amount of oxygen included in the oxide having a stoichiometric composition. For example, when the transition metal is tantalum (Ta), the stoichiometric composition of oxide is Ta₂O₅, which can be expressed as TaO_{2.5}. The degree of oxygen deficiency of TaO_{2.5} is 0%. For example, the degree of oxygen deficiency of an oxygen-deficient tantalum oxide having a composition of TaO_{1.5} equals to (2.5−1.5)/2.5=40%. An oxide having a low degree of oxygen deficiency is similar to an oxide having a stoichiometric composition, and thus has a high resistance value, whereas an oxide having a high degree of oxygen deficiency is similar to the metal included in the oxide, and thus has a low resistance value. The oxygen content atomic percentage of Ta₂O₅ is the ratio (O/(Ta+O)) of the number of oxygen atoms to the total number of atoms, which is 71.4 atm %. Therefore, the oxygen content atomic percentage of an oxygen-deficient tantalum oxide is higher than 0 and lower than 71.4 atm %.

A resistance change phenomenon presumably occurs due to an oxidation reduction reaction of a transition metal having a plurality of oxidation states. An oxidation reduction reaction occurs due to a voltage (or current) applied to a variable resistance layer. When a voltage or current higher than or equal a predetermined threshold voltage or current is applied to a variable resistance layer, an oxidation reduction reaction presumably occurs in the variable resistance layer, and the resistance changes. With a stacked structure including a low oxygen-deficient layer (high resistance layer) and a high oxygen-deficient layer (low resistance layer) applied to the variable resistance layer, the majority of the voltage applied to the variable resistance layer is presumably distributed to the high resistance layer, and thus resistance change phenomenon is presumably caused to occur stably in the high resistance layer. In this case, the entire high resistance layer does not undergo a change of resistance, but part of the high resistance layer presumably undergoes a change of resistance. Hereinafter, the case will be described where the oxygen-deficient transition metal oxide has two layers comprising the same transition metal, i.e., the oxygen-deficient transition metal oxide has a first variable resistance layer as a high oxygen concentration content layer (low oxygen-deficient layer), and a second variable resistance layer as a low oxygen concentration content layer (high oxygen-deficient layer). First, when a tantalum oxide is used as the oxygen-deficient transition metal oxide, the oxygen content atomic percentage of the first variable resistance layer (TaO_{y}), which is a high oxygen concentration content layer, is preferably 67.7 atm % or greater (2.1≦y), and the oxygen content atomic percentage of the second variable resistance layer (TaOₓ), which is a low oxygen concentration content layer, is preferably from 44.4 to 65.5 atm % (0.8≦x≦1.9). When a hafnium oxide is used as the oxygen-deficient transition metal oxide, the oxygen content atomic percentage of the first variable resistance layer (HfO_{y}), which is a high oxygen concentration content layer, is preferably greater than 64.3 atm % (1.8<y), and the oxygen content atomic percentage of the second variable resistance layer (HfOₓ), which is a low oxygen concentration content layer, is preferably from 47.4 to 61.5 atm % (0.9≦x≦1.6). When a zirconium oxide is used as the oxygen-deficient transition metal oxide, the oxygen content atomic percentage of the first variable resistance layer (ZrO_{y}), which is a high oxygen concentration content layer, is preferably greater than 65.5 atm % (1.9<y), and the oxygen content atomic percentage of the second variable resistance layer (ZrOₓ), which is a low oxygen concentration content layer, is preferably from 47.4 to 58.3 atm % (0.9≦x≦1.4).

In the case where the high oxygen concentration content layer is formed by, for example, plasma oxidation of the surface of a low oxygen concentration content layer, it is also possible to have the high oxygen concentration content layer include excessive oxygen more than the stoichiometric composition.

The thickness of the first variable resistance layer, which is a high oxygen concentration content layer, is preferably from 1 to 8 nm when TaO_{y} is used, preferably from 3 to 4 nm when HfO_{y} is used, and preferably from 1 to 5 nm when ZrO_{y} is used.

The transition metal comprised in the low oxygen-deficient layer (high resistance layer) and the transition metal comprised in the high oxygen-deficient layer (low resistance layer) may be different. As the transition metal, tantalum (Ta), titanium (Ti), hafnium (Hf), a zirconium (Zr), niobium (Nb), tungsten (W), and the like may be used. In the above case, the standard electrode potential of the transition metal comprised in the high resistance layer is preferably lower than the standard electrode potential of the transition metal comprised in the low resistance layer. The standard electrode potential exhibits characteristics such that higher the value thereof, the more resistant to oxidation. That is to say, by setting the standard electrode potential of the transition metal comprised in the high resistance layer lower than the standard electrode potential of the transition metal comprised in the low resistance layer, an oxidation reduction reaction in the high resistance layer is more likely to occur. For example, it is favorable to use TiO₂ for the high resistance layer and to use an oxygen-deficient tantalum oxide (TaOₓ, 0.8≦x≦1.9) for the low resistance layer. The standard electrode potential of Ti is −1.63 eV, the standard electrode potential of Ta is −0.6 eV, and thus resistance change phenomenon in TiO₂ layer occurs in a more stable manner.

It is to be noted that regardless of whether which material is comprised in the first variable resistance layer (high resistance layer), in some cases, an initial breakdown is necessary in order to cause the state immediately after manufacture to change to a state in which the variable resistance element can stably change its resistance. When the resistance value of the high resistance layer immediately after manufacture is usually higher than a high resistance state which allows a resistance change, the initial breakdown is normally performed once in order to form a low resistance region (filament) using part of the high resistance layer. When the thickness of the first variable resistance layer (high resistance layer) is increased, a voltage which is necessary for the initial breakdown increases, the voltage being applied to the variable resistance layer 112 immediately after manufacture in order to cause the variable resistance layer 112 to change to a state which allows a resistance change. That is to say, it is not desirable that the thickness of the first variable resistance layer should be greater than the above-mentioned preferable thickness, because the greater thickness may cause a breakdown of the current steering element 142 such as a diode which is connected to the variable resistance element 141 in series. On the other hand, regardless of whether which material is comprised in the first variable resistance layer, by designing the first variable resistance layer to have a lower degree of oxygen deficiency, a voltage is easily applied to the vicinity of the interface with the electrode which is in contact with the first variable resistance layer, and thus an initial breakdown can occur with a low voltage. That is to say, it is desirable that the first variable resistance layer be designed to have a low degree of oxygen deficiency because the low degree of oxygen deficiency is likely to trigger a resistance change due to oxidation and reduction.

In this manner, even when the oxygen-deficient transition metal oxide has a stacked structure including two layers, favorable memory cell characteristics, which allow an initial breakdown to occur with a low voltage, can be obtained.

Hereinafter, description of the configuration of the variable resistance element 141 will be continued.

The second lower electrode layer 111 is formed on the first upper electrode layer 110. The second upper electrode layer 113 is formed on the variable resistance layer 112. The second lower electrode layer 111 and the second upper electrode layer 113 comprise a precious metal such as platinum, iridium, and palladium, for example.

Here, the standard electrode potentials of platinum, iridium, and palladium are 1.18 ev, 1.16 eV, and 0.95 eV, respectively. In general, the standard electrode potential is an indicator of resistance to oxidation, and a higher value thereof means higher resistance to oxidation, and a lower value thereof means lower resistance to oxidation. That is to say, resistance change phenomenon is more likely to occur for greater difference between the standard electrode potentials of the electrode (the second lower electrode layer 111 and the second upper electrode layer 113) and the metal comprised in the variable resistance layer 112, whereas resistance change phenomenon is less likely to occur for smaller difference therebetween. In view of the above discussion, it is estimated that likelihood of oxidation of the material of the variable resistance layer with respect to the electrode material plays a significant role in the mechanism of the resistance change phenomenon.

For example, the standard electrode potential of tantalum is −0.60 eV, and the standard electrode potential of hafnium is −1.55 eV. The standard electrode potential of tantalum and the standard electrode potential of hafnium is lower than each of the standard electrode potentials of platinum, iridium, and palladium. Consequently, an oxidation reduction reaction of a tantalum oxide or a hafnium oxide presumably occurs in the vicinity of the interface between the electrode (the second lower electrode layer 111 or the second upper electrode layer 113) comprising any one of platinum, iridium and palladium, and the variable resistance layer 112, oxygen is transferred, and resistance change phenomenon occurs. Specifically, the variable resistance layer 112 comprising an oxygen-deficient transition metal oxide such as a tantalum oxide, a hafnium oxide, a zirconium oxide, a titanium oxide changes from a low resistance state to a high resistance state with an applied voltage for which the absolute value of a first polarity (positive or negative) is greater than or equal to a first threshold value. On the other hand, the variable resistance layer 112 changes from a high resistance state to a low resistance state with an applied voltage for which the absolute value of a second polarity (positive or negative) is greater than or equal to a second threshold value, the second polarity being different from the first polarity. That is to say, the variable resistance layer 112 exhibits bipolar resistance change characteristics.

Here, the case is specifically described where the variable resistance layer 112 comprises a transition metal oxide which has a stacked structure of layers with different degrees of oxygen deficiency. First, a voltage to be applied to the electrode (the second upper electrode layer 113 or the second lower electrode layer 111) in contact with the first variable resistance layer which is a low oxygen-deficient layer, is assumed to be positive with respect to the electrode (the second lower electrode layer 111 or the second upper electrode layer 113) in contact with the second variable resistance layer which is a high oxygen-deficient layer. In this case, a voltage, which has a positive polarity and is higher than or equal to the first threshold value, is applied to the first variable resistance layer, and thus oxygen ions in a variable resistance film (particularly, a filament) cluster around the nearby vicinity of the second lower electrode layer 111 or the second upper electrode layer 113, and the first variable resistance layer changes from a low resistance state to a high resistance state. On the other hand, a voltage to be applied to the electrode (the second upper electrode layer 113 or the second lower electrode layer 111) in contact with the first variable resistance layer is assumed to be negative with respect to the electrode (the second lower electrode layer 111 or the second upper electrode layer 113) in contact with the second variable resistance layer. In this case, a voltage, which has a negative polarity and is higher than or equal in absolute value to the second threshold value, is applied to the variable resistance layer 112, and thus unevenly distributed oxygen ions in the vicinity of the second lower electrode layer 111 or the second upper electrode layer 113 and in the first variable resistance layer (particularly, the filament) diffuse to the adjacent region, and the first variable resistance layer changes from a high resistance state to a low resistance state.

The variable resistance element 141 is formed as described above.

The third interlayer insulating layer 116 covers the variable resistance element 141 and the current steering element 142, and is formed on the second interlayer insulating layer 105. The drawing contact 118 and the wiring groove are formed in the third interlayer insulating layer 116, and the second wiring 119 is embedded and formed in the drawing contact 118 and the wiring groove.

The third barrier metal layer 117 is formed in the drawing contact 118 in the third interlayer insulating layer 116 and the wiring groove. The third barrier metal layer 117 is formed by depositing tantalum nitride having a thickness of 5 to 40 nm, and tantalum having a thickness of 5 to 40 nm, for example.

The second wiring 119 is formed in the third interlayer insulating layer 116, and is connected to the upper portion of the variable resistance element 141, i.e., the second upper electrode layer 113 included in the variable resistance element 141. The second wiring 119 is connected to the drawing contact 118, and thus is also connected to the first wiring 103 for peripheral wiring of the memory cell array.

The nonvolatile memory element 10 is formed as described above.

At least the area of the variable resistance layer 112 of the above-described variable resistance elements 141 is smaller than the area of the current steering element 142. The current steering element 142 is a surface parallel to the above-mentioned substrate, and has a step surface 110b which is a surface having the area based on the area difference between the variable resistance layer 112 of the variable resistance element 141 and the current steering element 142. Hereinafter, these characteristics of the variable resistance element 141 and the current steering element 142 will be described with reference to the drawings.

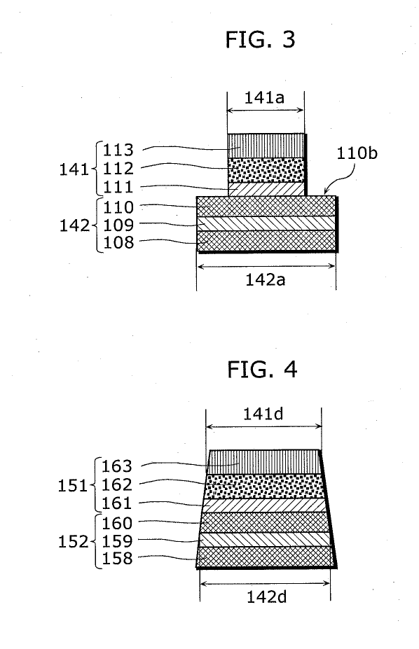

FIG. 3 is a cross-sectional view of the variable resistance element and the current steering element which are included in the nonvolatile memory element according to Embodiment 1 of the present invention.

The variable resistance element 141 includes the second lower electrode layer 111, the variable resistance layer 112, and the second upper electrode layer 113, and the current steering element 142 includes the first lower electrode layer 108, the current steering layer 109, and the first upper electrode layer 110. The width of the variable resistance element 141 is indicated by a variable resistance element width 141a, which is the same as the width of the second lower electrode layer 111, the variable resistance layer 112, or the second upper electrode layer 113. On the other hand, the width of the current steering element 142 is indicated by a current steering element width 142a, which is the same as the width of the first lower electrode layer 108, the current steering layer 109, and the first upper electrode layer 110. The width (element width) in the above situation may be formed, for example, with a square with a side having the above-mentioned element width, or a circle with a diameter having the above-mentioned element width when the element is viewed from above the upper surface.

As illustrated in FIG. 3, the current steering element width 142a is set to be greater than the variable resistance element width 141a. In other words, the width (area) of the variable resistance element 141 at least in a direction parallel to the variable resistance layer 112 is smaller than the width (area) in a direction parallel to the layers of the current steering element 142. As illustrated in FIG. 3, the current steering element 142 has the step surface 110b. Here, the step surface 110b is a surface parallel to the substrate, and has the area according to at least the width difference between the variable resistance layer 112 of the variable resistance element 141 and the current steering element 142. That is to say, the variable resistance element 141 is disposed on and within the upper surface of the first upper electrode layer 110 of the current steering element 142.

Here, the variable resistance elements 141 and the current steering element 142 are formed by the below-described characteristic manufacturing method of the present invention, specifically, only by the step of patterning the variable resistance element 141 and the current steering element 142 after the step of depositing respective electrode layers, the variable resistance layer 112, and the current steering layer 109 in order to form the variable resistance element 141 and the current steering element 142. Description is omitted because the details will be described below.

By forming the variable resistance element 141 and the current steering element 142 by the above manufacturing method, the dimensions of the variable resistance element width 141a of the variable resistance element 141 and the current steering element width 142a of the current steering element 142 can be increased while the interface state of the variable resistance element 141 and the current steering element 142 is maintained stably.

Next, a comparative example will be described where the dimension difference between the variable resistance element and the current steering element is formed by a general manufacturing method, and not by the characteristic manufacturing method of the present invention.

FIG. 4 is a cross-sectional view of a variable resistance element and a current steering element which are included in a nonvolatile memory element according to the comparative example.

The variable resistance element 151 includes the second lower electrode layer 161, the variable resistance layer 162, and the second upper electrode layer 163, and the current steering element 152 includes the first lower electrode layer 158, the current steering layer 159, and the first upper electrode layer 160. The width of the variable resistance element 151 is indicated by a variable resistance element width 141d. Unlike the case in FIG. 3, the variable resistance element width 141d is the same as the width of the second upper electrode layer 163, however, the widths of the second lower electrode layer 161 and the variable resistance layer 162 are different. On the other hand, the width of the current steering element 152 is indicated by a current steering element width 142d. Unlike the case in FIG. 3, the current steering element width 142d is the same as the width of the first upper electrode layer 160, however, the widths of the current steering layer 159 and the first lower electrode layer 158 are different.

The variable resistance element 151 and the current steering element 152 which are illustrated in FIG. 4 are formed as follows. That is to say, first, the first lower electrode layer 158, the current steering layer 159, the first upper electrode layer 160, the second lower electrode layer 161, the second upper electrode layer 163, and the variable resistance layer 162 are all formed. Next, the side walls of the variable resistance element 151 and the current steering element 152 are patterned with a tapered angle of less than 90 degrees using a single mask pattern. In this manner, the variable resistance element 151 and the current steering element 152 are formed, so that the current steering element width 142d is greater from the variable resistance element 141d in width.

Therefore, in the comparative example illustrated in FIG. 4, the connecting surface between the variable resistance element 151 and the current steering element 152 has less process damage such as roughness on a film surface, and a variation in the film thickness due to CMP processing on the connecting surface, for example, in the step of forming a variable resistance element in a contact hole, and thus a stable connecting surface (interface state) can be obtained. However, because the difference between the widths of the variable resistance element 151 and the current steering element 152 is small, a sufficient amount of current necessary for an initial breakdown for a resistance change operation of the variable resistance element 151 can not be obtained. For example, by forming a small angle of the side wall (tapered shape), the width difference between the variable resistance element 151 and the current steering element 152 is increased, so that a necessary and sufficient amount of current for the variable resistance element 151 is obtained. Even in this case, a variation in characteristics due to a variation in dimensions increases, and thus stable operation may not be obtained. That is to say, a width difference for allowing above-mentioned step surface 110b is not obtained by the conventional manufacturing method.

With the nonvolatile memory element 10 having the above configuration, by setting the current steering element width 142a (area of the current steering element 142) of the current steering element 142 to be greater than the variable resistance element width 141a (area of the variable resistance element 141) of the variable resistance element 141, the allowable current of the current steering element 142 can be increased. That is to say, a breakdown of the current steering element 142 at the time of an initial operation of the variable resistance element 141 can be prevented.

With a cross-point configuration in which the nonvolatile memory element includes a combination of the variable resistance element 141 and the current steering element 142 as a memory cell, occurrence of write disturb of adjacent memory cells can be reliably prevented. Accordingly, a variable resistance nonvolatile memory element which allows large capacity and high integration can be achieved without disposing a switching device such as a transistor or the like.

Next, a method of manufacturing the aforementioned nonvolatile memory element 10 will be described.

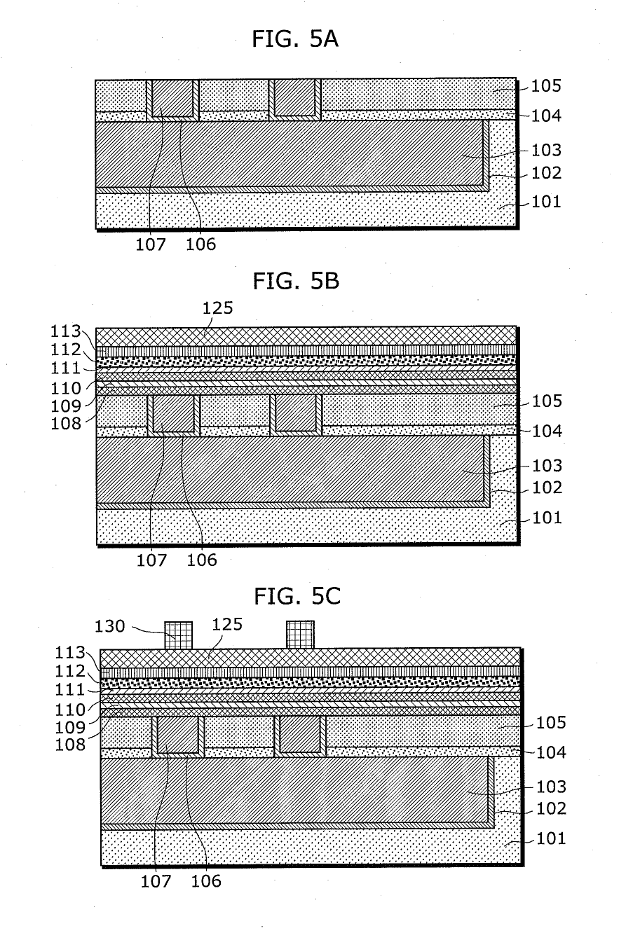

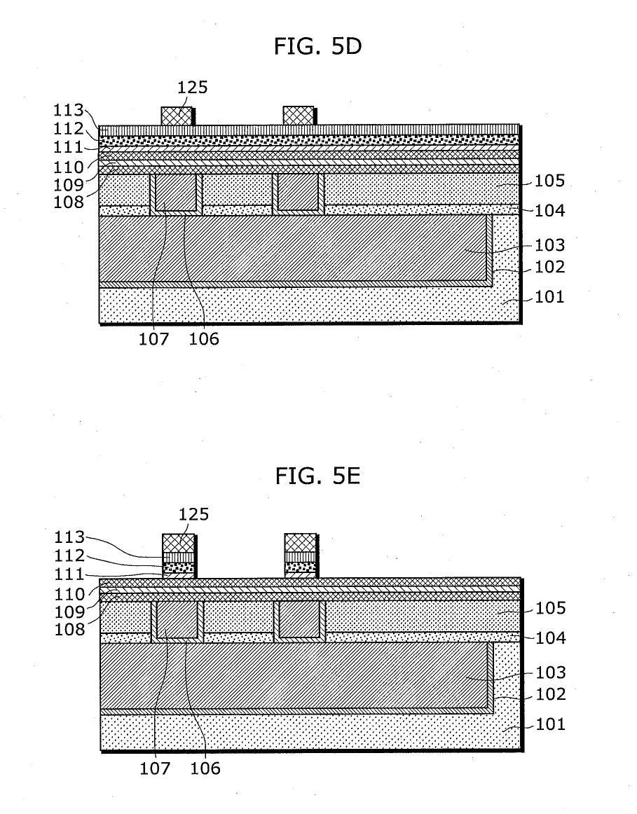

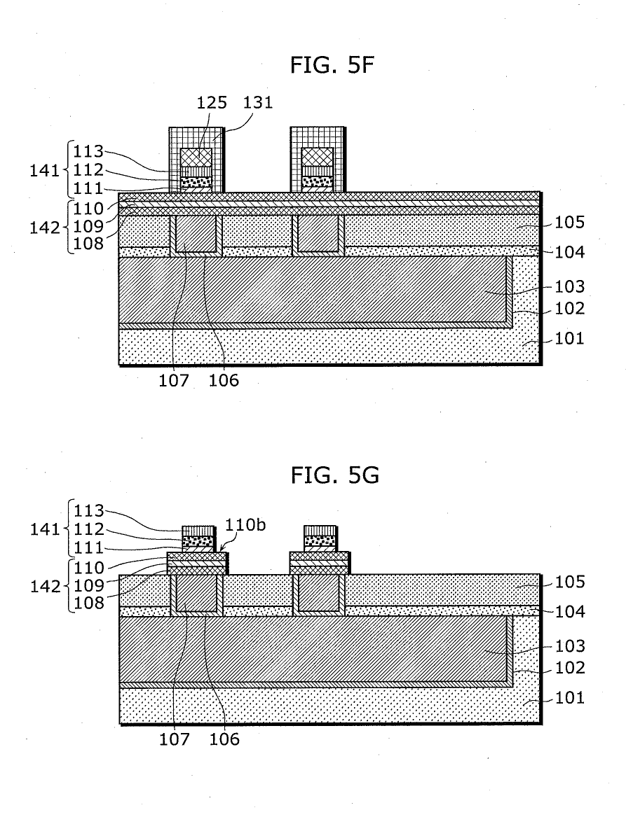

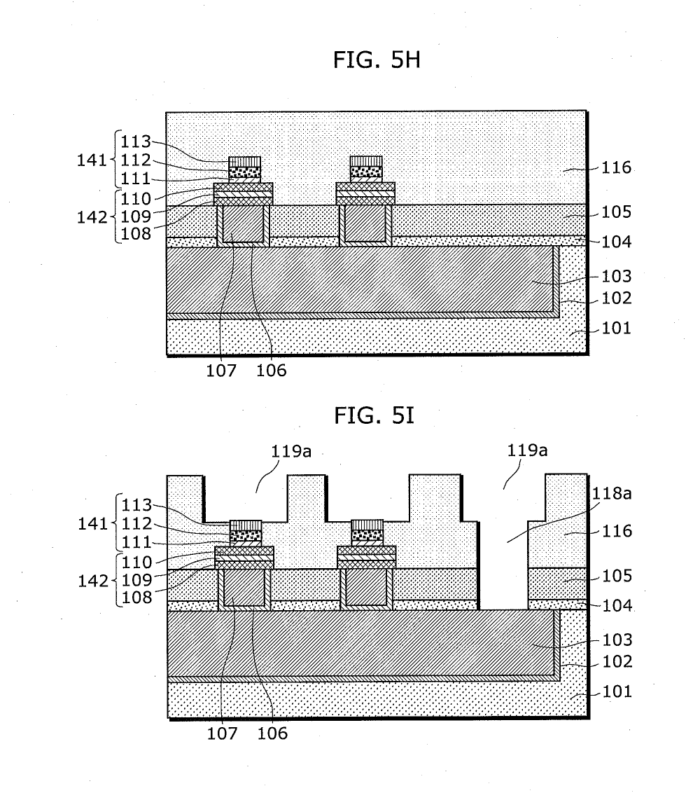

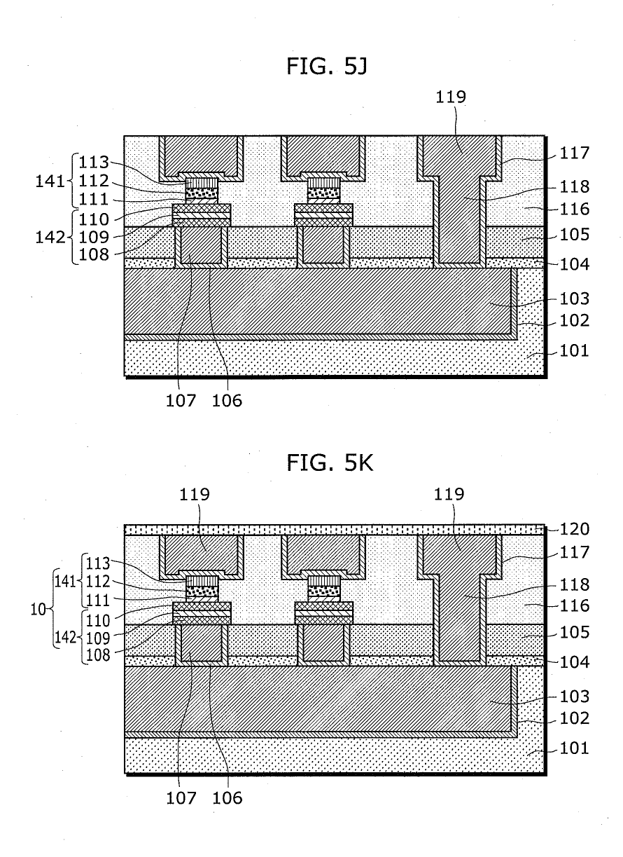

FIGS. 5A to 5K illustrate a method of manufacturing the nonvolatile memory element 10 according to Embodiment 1 of the present invention. In a normal situation, a large number of the nonvolatile memory elements 10 are formed on a substrate, however, for the sake of simplicity of the drawing, the case is illustrated where only two pieces of a variable resistance element and a current steering element are formed. Part of the configuration is enlarged for the sake of easy understanding.

First, as illustrated in FIG. 5A, the first wiring 103 is formed on a semiconductor substrate on which a transistor or the like is formed, and the plug 107, which is connected to the first wiring 103, is formed on the wiring 103 formed.

Specifically, the first interlayer insulating layer 101 comprising a silicon oxide is formed on a semiconductor substrate using a method such as plasma CVD. Subsequently, a wiring groove for embedding and forming the first wiring 103 formed into the first interlayer insulating layer 101 is formed by photolithography and dry etching. Subsequently, the first barrier metal layer 102 including tantalum nitride (having a thickness of 5 to 40 nm) and tantalum (having a thickness of 5 to 40 nm), and copper as wiring material (having a thickness of 50 to 300 nm) which serves as a seed layer are deposited in the wiring groove formed using a method such as sputtering. Then copper is further deposited using copper as a seed by a method such as electroplating, and thus the entire wiring groove is filled with the wiring material of copper. Subsequently, excessive copper out of the deposited copper and excessive first barrier metal layer 102 on the surface are removed by the CMP method so as to planarize the surface of the first interlayer insulating layer 101 and the surface of the first wiring 103, and thus the first wiring 103 is formed.

Subsequently, using a method such as plasma CVD, silicon nitride is deposited with a thickness from 30 to 200 nm, and the first liner layer 104 is formed so as to cover the first interlayer insulating layer 101 and the surface of the first wiring 103. Subsequently, the second interlayer insulating layer 105 is further deposited on the first liner layer 104 formed. Here, when necessary, step on the surface is reduced by the CMP method. Subsequently, a contact hole for embedding and forming the plug 107 to be connected to the first wiring 103 is formed at a predetermined position on the first wiring 103 by photolithography and dry etching. Subsequently, the second barrier metal layer 106 including tantalum nitride (having a thickness of 5 to 40 nm) and tantalum (having a thickness of 5 to 40 nm), and copper as wiring material (having a thickness of 50 to 300 nm) which serves as a seed layer are deposited on the second interlayer insulating layer 105 having the formed contact hole using a method such as sputtering. Then copper is further deposited using copper as a seed by a method such as electroplating, and thus the entire contact hole is filled with the second barrier metal layer 106 and copper, and the plug 107 is formed. Subsequently, excessive copper and second barrier metal layer 106 on the surface are removed by the CMP method so as to planarize the surface of the first interlayer insulating layer 101 and the surface of the first wiring 103, and thus the first wiring 103 is formed.

Next, as illustrated in FIG. 5B, the first lower electrode layer 108 (having a thickness of 20 nm) comprising tantalum nitride, the current steering layer 109 (having a thickness of 20 nm) comprising nitrogen-deficient silicon nitride, and the first upper electrode layer 110 (having a thickness of 30 nm) comprising tantalum nitride are deposited in this order on the second interlayer insulating layer 105 including the plug 107 by using a method such as sputtering. Subsequently, the second lower electrode layer 111 (having a thickness of 30 nm) comprising tantalum nitride, the variable resistance layer 112, and the second upper electrode layer 113 (having a thickness of 80 nm) comprising iridium are deposited in this order on the first deposited upper electrode layer 110 by using a method such as sputtering. Subsequently, a hard mask layer 125 (having a thickness of 100 nm) which is a conductive layer and comprises either titanium nitride or titanium aluminum nitride (for example, titanium aluminum nitride) is deposited as a hard mask at the time of dry etching on the deposited second upper electrode layer 113.

Here, the variable resistance layer 112 may have a single layer structure including an oxygen-deficient transition metal oxide, however, preferably have a stacked structure. When the variable resistance layer 112 has a stacked structure, TaOₓ (0.8≦x≦1.9) as a high oxygen-deficient layer (second variable resistance layer) is deposited with a thickness of 50 nm, and TaO_{y} as a low oxygen-deficient layer (first variable resistance layer) having a degree of oxygen deficiency lower than that of TaOₓ may be deposited with a thickness of 5 nm (formed by a sputtering method using a Ta₂O₅ target) on the previously deposited high oxygen-deficient layer (second variable resistance layer). In the above step, in forming the variable resistance layer 112, after TaOₓ is deposited with a thickness of 50 nm, the upper surface of TaOₓ may be oxidized by plasma oxidation in an oxygen atmosphere, and TaO_{y} (here, Ta₂O₅) as a low oxygen-deficient layer (first variable resistance layer) having more oxygen content than TaOₓ may be deposited with a thickness of 5 nm on the deposited high oxygen-deficient layer (second variable resistance layer). The method of oxidation treatment is not limited to the plasma oxidation, and may be, for example, a treatment which is effective in oxidizing the surface, such as heat treatment in an oxygen atmosphere. The thickness of the high oxygen-deficient layer (second variable resistance layer) TaOₓ is not limited to 50 nm, and the high oxygen-deficient layer (second variable resistance layer) TaOₓ may be deposited with a thickness of 45 nm, and subsequently, TaO_{y} (here, Ta₂O₅) as the low oxygen-deficient layer (first variable resistance layer) may be deposited with a thickness of 5 nm instead of performing oxidation treatment. Optionally, a low oxygen-deficient titanium oxide may be deposited as the low oxygen-deficient layer (first variable resistance layer) instead of TaO_{y}.

Hereinafter, the first lower electrode layer 108, the current steering layer 109, the first upper electrode layer 110, the second lower electrode layer 111, the variable resistance layer 112, the second upper electrode layer 113, and the hard mask layer 125 are not only in a state where the layers are etched in a pattern, but also in a state where the layers are formed before etched.

Next, as illustrated in FIG. 5C, a first mask pattern 130 in a dot shape for forming the variable resistance element 141 is formed using photolithography. Here, the first mask pattern 130 is a photoresist mask pattern having a side of 200 nm, for example.

Next, as illustrated in FIG. 5D, the hard mask layer 125 is patterned using the first mask pattern 130, and subsequently, the first mask pattern 130 is removed by ashing treatment.

Next, as illustrated in FIG. 5E, the second upper electrode layer 113, the variable resistance layer 112, and the second lower electrode layer 111 which constitute the variable resistance element 141 are patterned by dry etching using the hard mask layer 125 which has been patterned by the first mask pattern. Thus, the variable resistance element 141 having the variable resistance element width 141a of 200 nm can be formed.

Next, as illustrated in FIG. 5F, a second mask pattern 131, which is larger than the first mask pattern 130, is formed using photolithography so as to cover the variable resistance element 141 formed in FIG. 5E, or in other words, so as not to expose the variable resistance element 141. Here, the second mask pattern 131 is a photoresist mask pattern having a side of 500 nm, for example. The second mask pattern 131 is larger than the first mask pattern 130, and covers the variable resistance element 141 including the second upper electrode layer 113, the variable resistance layer 112, and the second lower electrode layer 111 which are patterned by the first mask pattern 130.

Next, as illustrated in FIG. 5G, the first upper electrode layer 110, the current steering layer 109, and the first lower electrode layer 108 which are included in the current steering element 142 are patterned by the first mask pattern using the second mask pattern 131 formed in FIG. 5F. Subsequently, the second mask pattern 131 is removed by ashing treatment, and the hard mask layer 125 is removed by etching, for example. The hard mask layer 125 does not need to be removed and may remain as needed. Accordingly, the current steering element 142 having the current steering element width 142a of 500 nm is formed and connected in series to the variable resistance element 141 having the variable resistance element width 141a of 200 nm.

Now, the current density necessary for an initial breakdown of the variable resistance element 141 is 600 kA/cm², the variable resistance element 141 being manufactured in the above-described manner using tantalum oxide having a thickness of e.g., 50 nm for the variable resistance layer 112, and using iridium having a thickness of e.g., 80 nm for the second upper electrode layer 113. On the other hand, the breakdown current density of the current steering element 142 manufactured in the above-described manner is 110 kA/cm². Therefore, in the case where the variable resistance element width 141a of the variable resistance element 141 and the current steering element width 142a of the current steering element 142 are the same width, the current steering element 142 breaks down when a current necessary for an initial breakdown of the variable resistance element 141 is applied to the current steering element 142.

Thus, in the present embodiment, the element width of the variable resistance element is formed to be smaller than the element width of the current steering element, so that the current steering element does not break down even when a current necessary for an initial breakdown for a resistance change is applied to the variable resistance element.

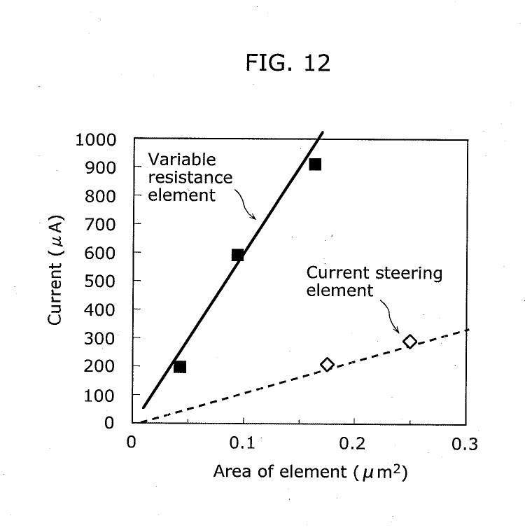

FIG. 12 illustrates graphs of relationships between the current value necessary for an initial breakdown of the variable resistance element 141, the breakdown current value of the current steering element 142, and respective element areas of the variable resistance element and the current steering element. The current value necessary for an initial breakdown decreases as the area of the variable resistance element 141 is decreased, and the breakdown current value increases as the area of the current steering element 142 is increased. When both elements are formed with the same element area, the relationship: the current value necessary for the variable resistance element to cause an initial breakdown > the breakdown current value of the current steering element is satisfied for any element area. Using the above characteristics, the element width of the variable resistance element is set to 200 nm, and the element width of the current steering element is set to 500 nm in the present embodiment. Thus, an initial breakdown of the variable resistance element can occur without causing the current steering element to break down. In the case where the element width (the current steering element width 142a) of the current steering element 142 is 500 nm (assumed square having a side of the element width has an area of 0.25 μm²), the current control breakdown current is approximately 275 μA. On the other hand, when the element width (the variable resistance element width 141a) of the variable resistance element 141 is 200 nm (assumed square having a side of the element width has an area of 0.04 μm²), the current necessary for an initial breakdown is approximately 240 μA. Therefore, even when the current necessary for an initial breakdown is applied to the variable resistance element 141, the effect is achieved that an initial breakdown of the variable resistance element can occur without causing the current steering element 142 to break down.

Next, as illustrated in FIGS. 5H and 5I, the third interlayer insulating layer 116 is formed so as to cover the variable resistance element 141 and the current steering element 142, and the second wiring 119 to be connected to the second upper electrode layer 113 included in the variable resistance element 141 is formed in the previously formed third interlayer insulating layer 116.

Specifically, first, as illustrated in FIG. 5H, the third interlayer insulating layer 116 for embedding and forming the second copper wiring is deposited so as to cover the variable resistance element 141 and the current steering element 142. Subsequently, as illustrated in FIG. 5I, a wiring groove 119a for embedding and forming the second wiring 119 into the third interlayer insulating layer 116 is formed by photolithography and dry etching, the wiring groove 119a being connecting to the second upper electrode layer 113 only. At the same time, a contact hole 118a for forming a drawing contact 118 to be connected to the first wiring 103 is formed at a predetermined position on the first wiring 103 which is not provided with the variable resistance element 141 and the current steering element 142, by photolithography and dry etching.

In general, the contact hole 118a for the drawing contact 118 is formed first by the photolithography and dry etching for the first time, and the wiring groove 119a for the second wiring 119 is formed by the photolithography and dry etching for the second time. However, the wiring groove 119a may be formed first.

Next, as illustrated in FIG. 5J, the third barrier metal layer 117 and copper as wiring material (having a thickness of 50 to 300 nm) are deposited into the contact hole 118a and the wiring groove 119a by a method such as sputtering, the third barrier metal layer 117 comprising tantalum nitride (having a thickness of 5 to 40 nm) and tantalum (having a thickness of 5 to 40 nm). Here, the conditions similar to those in the above-described step of embedding and forming the first wiring 103 are used. Then copper is further deposited using copper as a seed by a method such as electroplating, and thus the entire wiring groove is filled with the wiring material of copper. Subsequently, excessive copper out of the deposited copper and excessive third barrier metal layer 117 on the surface are removed by the CMP method so as to planarize the surface of the third interlayer insulating layer 116 and the surface of the second wiring 119, and thus the second wiring 119 is formed.

Next, as illustrated in FIG. 5K, a silicon nitride layer is deposited with a thickness of 30 to 200 nm, for example, with a thickness of approximately 50 nm so as to cover the second wiring 119 using a method such as plasma CVD, and thus the second liner layer 120 is formed.

As described above, by the manufacturing method of the present embodiment, the effective area of the current steering element can be made larger than the area of operation of the variable resistance element only by the step of patterning each element (the step of forming each element by dry etching using two mask patterns) after the step of depositing respective electrodes, variable resistance layers, and current steering layers which are included in the variable resistance element and the current steering element. Consequently, the effect is achieved that it is possible to easily manufacture a nonvolatile memory element in which even when a current steering element in a conventional configuration is used, a larger amount of current can flow without causing the current steering element to break down, and a necessary and sufficient amount of current for operating the variable resistance element (operation including an initial break) can flow through the variable resistance element.

In the present embodiment, the manufacturing method is described where the second upper electrode layer 113 of the variable resistance element 141 comprises iridium, however, the constituent is not limited to iridium. The second upper electrode layer 113 may comprises, for example, any metal of platinum, iridium and palladium, or a combination, alloy of these metals. In this case, the effect is achieved that an initial breakdown voltage can be reduced, while reduction and variation in the initial resistance is prevented.

Therefore, the nonvolatile memory device can be manufactured by a semiconductor process using the conventional CMOS process or the like, and thus a specific and special semiconductor process does not need to be used in manufacturing the variable resistance element and the current steering element. Consequently, the nonvolatile memory device can be manufactured with improved compatibility with advanced semiconductor miniaturization processes.

In the present embodiment, the first upper electrode layer 110 and second lower electrode layer 111 comprise the same material, however, this is not a limitation. Different materials of the aforementioned materials may be used for the layers.

The first upper electrode layer 110 and the second lower electrode layer 111 may comprise the same material, and thus the variable resistance element 141 and the current steering element 142 may share the same electrode as the electrodes thereof. In this case, similar effects can be achieved by patterning up to at least the variable resistance layer 112 with the first mask pattern.

### Embodiment 2

Next, a nonvolatile memory element 20 in Embodiment 2 of the present invention will be described.

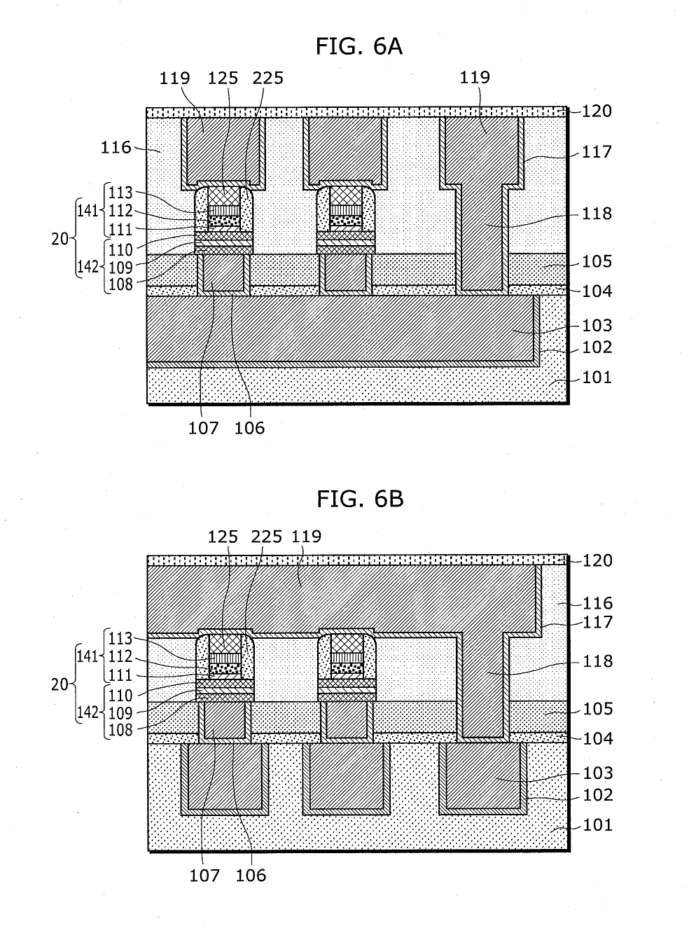

FIGS. 6A and 6B are each a cross-sectional view illustrating a configuration example of a nonvolatile memory element according to Embodiment 2 of the present invention. Similar components to those in FIGS. 2A and 2B are labeled with the same reference symbols, and detailed description is omitted. The plan view illustrating the configuration example of the nonvolatile memory element 20 is similar to FIG. 1. That is to say, FIG. 6A corresponds to the cross-sectional view, as seen in an arrow direction, taken along the chain line indicated by A-A′ in FIG. 1, and FIG. 6B corresponds to the cross-sectional view, as seen in an arrow direction, taken along the chain line indicated by B-B′ in FIG. 1.

The nonvolatile memory element 20 illustrated in FIGS. 6A and 6B differs from the nonvolatile memory element 10 of Embodiment 1 illustrated in FIGS. 2A and 2B in that the nonvolatile memory element 20 is provided with the hard mask layer 125 and a sidewall layer 225.

The hard mask layer 125 is a conductive layer, and is formed on the variable resistance element 141, or more specifically, on the second upper electrode layer 113 out of the second lower electrode layer 111, the variable resistance layer 112, and the second upper electrode layer 113 which are included in the variable resistance element 141.

The sidewall layer 225 is formed on the side wall portions of the variable resistance element 141 and the hard mask layer 125, and comprises, for example, an insulating material such as silicon nitride.

The first wiring 103 and the second wiring 119 three-dimensionally intersecting the first wiring 103 are connected to the hard mask layer 125 which is formed above the variable resistance element 141.

The nonvolatile memory element 20 is formed as described above.

The nonvolatile memory element 20 also has similar characteristics to those of the nonvolatile memory element 10 in Embodiment 1. That is to say, the area of at least the variable resistance layer 112 of the variable resistance element 141 is smaller than the area of the current steering element 142. The current steering element 142 is a surface parallel to the above-mentioned substrate, and has a step surface which is a surface having the area based on the area difference between the variable resistance layer 112 of the variable resistance element 141 and the current steering element 142. Hereinafter, these characteristics of the variable resistance element 141 and the current steering element 142 will be described with reference to the drawings.

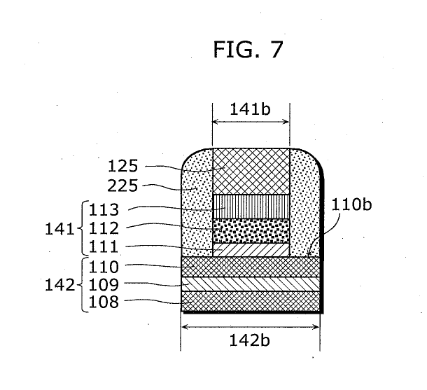

FIG. 7 is a cross-sectional view of the variable resistance element and the current steering element which are included in the nonvolatile memory element according to Embodiment 2 of the present invention. Similar components to those in FIG. 3 are labeled with the same reference symbols, and detailed description is omitted.

The hard mask layer 125 is formed on the variable resistance element 141, and the sidewall layer 225 is formed on the side wall portions of the variable resistance element 141 and the hard mask layer 125.

The dimension width of the variable resistance element 141 is indicated by a variable resistance element width 141b, which is the same as the width of one of the second lower electrode layer 111, the variable resistance layer 112, the second upper electrode layer 113, and the hard mask layer 125. On the other hand, the dimension width of the current steering element 142 is indicated by a current steering element width 142b, which is the same as the width of one of the first lower electrode layer 108, the current steering layer 109, and the first upper electrode layer 110.

As illustrated in FIG. 7, the current steering element width 142b is formed to be greater than the variable resistance element width 141b. In other words, the width (area) of the variable resistance element 141 at least in a direction parallel to the variable resistance layer 112 is smaller than the width (area) of the current steering element 142 in a direction parallel to the layers in the current steering element 142. As illustrated in FIG. 7, the current steering element 142 has the step surface 110b. Here, the step surface 110b is a surface parallel to the substrate, and has the area according to at least the width difference (dimension difference) between the variable resistance layer 112 of the variable resistance element 141 and the current steering element 142.

The variable resistance element 141 and the current steering element 142 are formed by the below-described characteristic manufacturing method of the present invention. In contrast to the variable resistance element 151 and the current steering element 152 which are illustrated in FIG. 4, the variable resistance element 141 and the current steering element 142 illustrated in FIG. 7 which are formed by the above-described manufacturing method maintain respective interface states stably, and can have an increased width dimension difference between the variable resistance element width 141b of the variable resistance element 141, and the current steering element width 142b of the current steering element 142.

With the nonvolatile memory element 20 having the above configuration, by setting the current steering element width 142b (area of the current steering element 142) of the current steering element 142 to be greater than the variable resistance element width 141b (area of the variable resistance element 141) of the variable resistance element 141, the allowable current of the current steering element 142 can be increased as described in Embodiment 1 with reference to FIG. 12, and thus current control breakdown due to an initial breakdown of the variable resistance element 141 can be prevented.

Next, a method of manufacturing the aforementioned nonvolatile memory element 20 will be described.

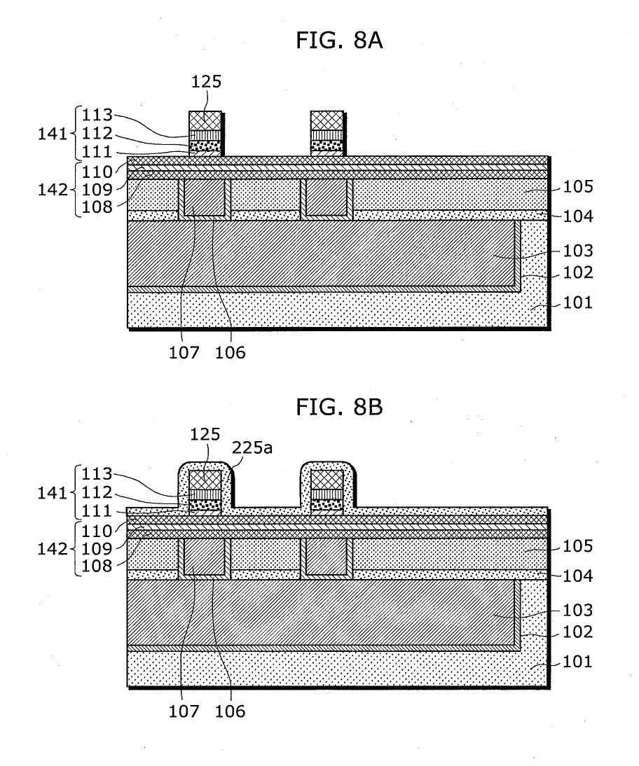

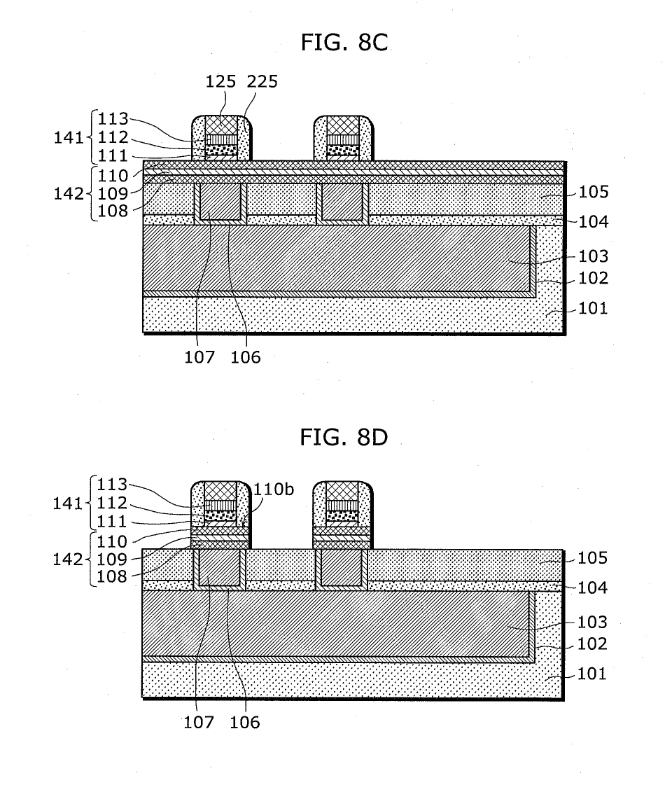

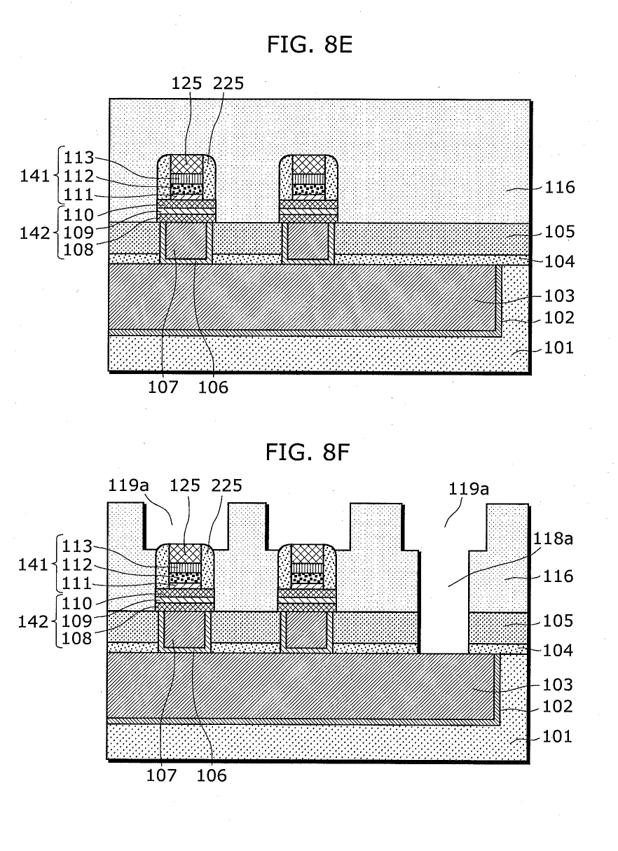

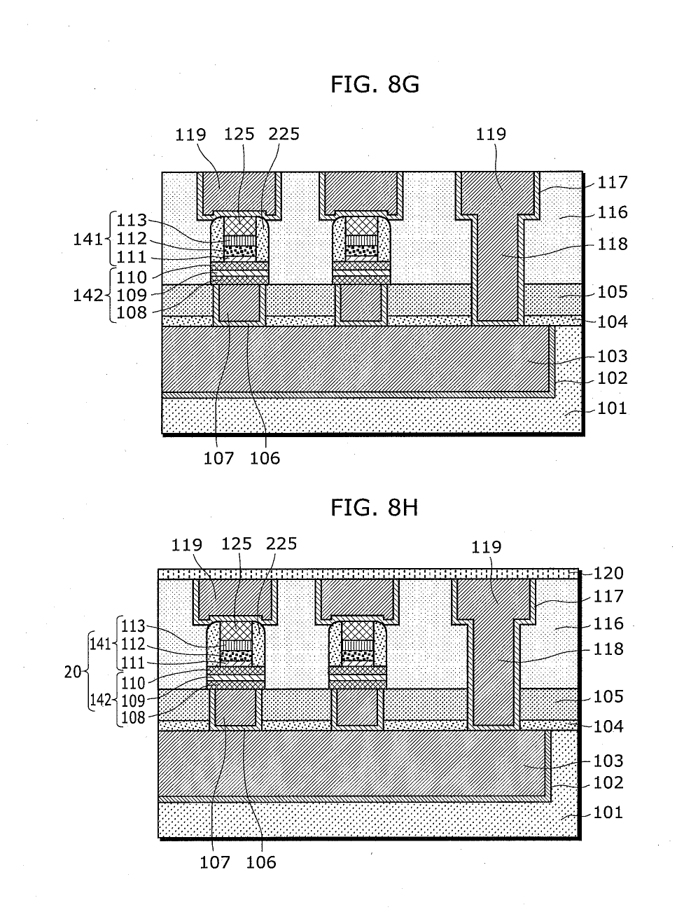

FIGS. 8A to 8H are each a cross-sectional view illustrating a method of manufacturing the nonvolatile memory element 20. Hereinafter, for the sake of simplicity of the drawing, the case is illustrated where only two pieces of a variable resistance element and a current steering element are formed. FIGS. 8A to 8H illustrate cross-sectional views of the steps which are different from the method of manufacturing the nonvolatile memory element 10 in Embodiment 1. Similar components to those in FIGS. 5A to 5K, FIGS. 6A, 6B, and 7 are labeled with the same reference symbols, and detailed description thereof is omitted.

First, as illustrated in FIG. 8A, the steps illustrated in FIGS. 5A and 5B and described in Embodiment 1 are performed, and the first mask pattern 130 for forming the variable resistance element 141 is applied to the hard mask layer 125, and subsequently, photolithography is performed to form the variable resistance element 141 (for example, FIG. 5C). Here, the first mask pattern 130 on which photolithography has been performed is a photoresist mask pattern with each side of 200 nm, for example. Subsequently, the hard mask layer 125 is patterned using the first mask pattern 130 on which photolithography has been performed, then the second lower electrode layer 111, the variable resistance layer 112, and the second upper electrode layer 113 are patterned using the patterned hard mask layer 125 as a mask, and thus the variable resistance element 141 having the variable resistance element width 141b of 200 nm is formed.

Next, as illustrated in FIG. 8B, an insulating layer 225a (having a thickness of 170 nm) comprising silicon nitride is deposited using plasma CVD so as to cover the hard mask layer 125, the variable resistance element 141, and the first upper electrode layer 110.

Next, as illustrated in FIG. 8C, the insulating layer 225a is formed on the first upper electrode layer 110 including the variable resistance element 141, and only the insulating layer 225a which is on the upper surface of the hard mask layer 125 and on the upper surface of the first upper electrode layer 110 excluding the variable resistance element 141 is removed by performing an etchback (anisotropic etching). By performing an etchback in this manner, the sidewall layer 225 can be formed on the side walls of the hard mask layer 125 and the variable resistance element 141.

Here, for example, there is a method using Reactive Ion Etching (RIE) as a method for performing etch back of the insulating layer 225a which comprises silicon nitride. When reactive ion etching is used, in general, the etching rate in an ion incident direction (vertical direction) is much faster than the etching rate in another direction (horizontal direction). Therefore, by performing etch back using reactive ion etching, it is possible for the insulating layer 225a to remain only on the side wall portion of the variable resistance element 141, and thus the sidewall layer 225 (having a thickness of 150 nm) can be formed.

Next, as illustrated in FIG. 8D, the first upper electrode layer 110, the current steering layer 109, and the first lower electrode layer 108 are patterned by dry etching using the region surrounded by the sidewall layer 225 formed in FIG. 8C and the hard mask layer 125 as a mask pattern, and thus the current steering element 142 is formed. Because the thickness of the sidewall layer 225 is 150 nm, and the variable resistance element width 141b of the variable resistance element 141 is 200 nm, the current steering element 142 connected to the variable resistance element 141 in series is formed to have the current steering element width 142b of 500 nm.

Now, a different point from Embodiment 1 is that the current steering element 142 is patterned by using as a mask pattern the region surrounded by the sidewall layer 225 which is uniformly formed on the side wall of the variable resistance element 141, without using the second mask pattern 131 which is needed in Embodiment 1. Because the second mask pattern 131 does not need to be used as stated above, the effect is achieved that the variable resistance element 141 and the current steering element 142 can be reliably formed in series in concentric circular shape regardless of mask alignment precision.

Similarly, in the present embodiment, the current density necessary for an initial breakdown of the variable resistance element 141 is 600 kA/cm², the variable resistance element 141 being manufactured in the above-described manner using tantalum oxide having a thickness of 50 nm for the variable resistance layer 112, and using iridium for the second upper electrode layer 113. On the other hand, the breakdown current density of the current steering element 142 manufactured in the above-described manner is 110 kA/cm². Therefore, in the case where the variable resistance element width 141b of the variable resistance element 141 and the current steering element width 142b of the current steering element 142 are the same width, the current steering element 142 breaks down when a current necessary for an initial breakdown of the variable resistance element 141 is applied to the current steering element 142.

Now, in the present embodiment, similarly to Embodiment 1, the element width (the variable resistance element width 141b) of the variable resistance element is formed to be smaller than the element width (the current steering element width 142b) of the current steering element, so that the current steering element 142 does not break down even when a current (including the current at the time of an initial breakdown) necessary for a resistance change is applied to the variable resistance element 141 (see FIG. 7). Specific examples of the dimensions of the variable resistance element 141, and the dimensions of the current steering element 142 are similar to those in the examples related to, for example, FIG. 12 of Embodiment 1. Therefore, description is omitted.

Next, as illustrated in FIGS. 8E to 8H, the third interlayer insulating layer 116 is formed so as to cover the variable resistance element 141 and the current steering element 142, and the second wiring 119 connected to the hard mask layer 125 is formed on the variable resistance element 141 and the current steering element 142 in the formed third interlayer insulating layer 116. Because these steps are similar to those illustrated in the above-described FIGS. 5H to 5K, the description other than the below-described different points is omitted.

In the step illustrated in FIG. 8E, the third interlayer insulating layer 116 for embedding and forming the second copper wiring is deposited so as to cover the variable resistance element 141 and the current steering element 142 including the sidewall layer 225. In the step illustrated in FIG. 8F, the wiring groove 119a for embedding and forming the second wiring 119 into the third interlayer insulating layer 116 is formed by photolithography and dry etching, the wiring groove 119a being connecting to the hard mask layer 125. Other steps are similar to those in Embodiment 1, and thus description is omitted.

In this manner, when the wiring groove 119a connected to the hard mask layer 125 is formed, the side wall portion of the variable resistance element 141 is covered by the sidewall layer 225, i.e., an insulating layer composing silicon nitride. Therefore, even when the bottom of the wiring groove 119a is connected to the hard mask layer 125 and is further deeply depressed, the sidewall layer 225 comprising an insulating layer is present at the side surface of the variable resistance layer 112, and thus the effect is achieved that the wiring groove 119a is prevented from being connected to the variable resistance layer 112. In other words, even when the third interlayer insulating layer 116 composing silicon oxides is etched, and further deeply depressed during the formation of the wiring groove 119a, the wiring groove 119a does not come into contact with the variable resistance layer 112 because the variable resistance layer 112 is covered by the sidewall layer 225 comprising an insulating layer.

Thus, the effect is achieved that a leak current can be prevented from flowing from the second wiring 119 into the variable resistance layer 112 not through the second upper electrode layer 113. In other words, when a current path is formed (a leak current flows) through which the current flows directly from the second wiring 119 to the variable resistance layer 112 not through the second upper electrode layer 113, an initial breakdown voltage necessary for forming a conductive path is not sufficiently applied by an initial breakdown at the time of a resistance change operation, and thus a resistance change operation is failed. On the other hand, in the present embodiment, a leak current can be prevented from flowing because the variable resistance element 141 is covered by the sidewall layer 225 as described above.

Because the steps illustrated in FIGS. 8G and 8H are similar to those illustrated in FIGS. 5J and 5K, description is omitted.

As described above, with the manufacturing method of the present embodiment, not only the effective area of the current steering element can be made larger than the area of operation of the variable resistance element using a single mask pattern without adding a particular step, but also the variable resistance element and the current steering element can be formed in series in symmetrical concentric circular shape when viewed from above the upper surface of the substrate. Consequently, the effect is achieved that it is possible to easily manufacture a nonvolatile memory element in which even when a current steering element in a conventional configuration is used, a larger amount of current can flow without causing the current steering element to break down, and a necessary and sufficient amount of current for operating the variable resistance element can flow through the variable resistance element. The current steering element in a conventional configuration is, for example, an MIM diode, an MSM diode, or a Schottky diode.

In addition, with the manufacturing method of the present embodiment, the two elements (the current steering element and the variable resistance element) having different sizes can be formed with a single mask pattern, and thus mask alignment accuracy is not necessary. Consequently, the effect is achieved that a specific and special semiconductor process does not need to be used in manufacturing the variable resistance element and the current steering element. In addition, the elements can be manufactured with a single mask pattern, thus the number of masks can be decreased, and the costs can be reduced.

Therefore, the nonvolatile memory device is compatible with advanced semiconductor miniaturization processes, and can be manufactured by a semiconductor process using the conventional CMOS process or the like, and thus the effect is achieved that the nonvolatile memory device with advanced miniaturization can be manufactured using semiconductor processes.

In the present embodiment, similarly to Embodiment 1, the manufacturing method is described where the second upper electrode layer 113 of the variable resistance element 141 comprises iridium, however, the constituent is not limited to iridium. The second upper electrode layer 113 may comprises, for example, any metal of platinum, iridium and palladium, or a combination, alloy of these metals. In this case, the effect is achieved that an initial breakdown voltage can be reduced, while reduction and variation in the initial resistance is prevented.

In the present embodiment, similarly to Embodiment 1, the first upper electrode layer 110 and second lower electrode layer 111 comprise the same material, however, this is not a limitation. Different materials of the aforementioned materials may be used for the layers.

The first upper electrode layer 110 and the second lower electrode layer 111 may comprise the same material, and thus the variable resistance element 141 and the current steering element 142 may share the same electrode as the electrodes thereof. In this case, similar effects can be achieved by patterning the second upper electrode layer 113, and the variable resistance layer 112 and part of the shared common electrode layer with the first mask pattern.

In the present embodiment, the case has been described where the nonvolatile memory element 20 is formed leaving the hard mask layer 125, however, this is not a limitation. For example, when the wiring groove 119a is formed by photolithography and dry etching in FIG. 8F, first, etching is performed until the hard mask layer 125 is exposed to the bottom of the wiring groove 119a, and etching is further performed until the first upper electrode layer 110 is exposed, then the hard mask layer 125 may be completely removed. In contrast to the case where the nonvolatile memory element 20 is formed leaving the hard mask layer 125, removing the hard mask layer 125 completely reduces a parasitic resistance and variation in contact resistance, and thus preferable.

In the present embodiment, patterning is performed using the region surrounded by the sidewall layer 225 and the hard mask layer 125 as a mask, however, the second upper electrode layer 113 may also be used as part of the mask instead of the hard mask layer 125. Specifically, a material having etching resistance (for example, iridium) may be comprised in the second upper electrode layer 113, and thus the second upper electrode layer 113 can serve as part of the mask.

### Embodiment 3

Next, a nonvolatile memory element 30 in Embodiment 3 of the present invention will be described.

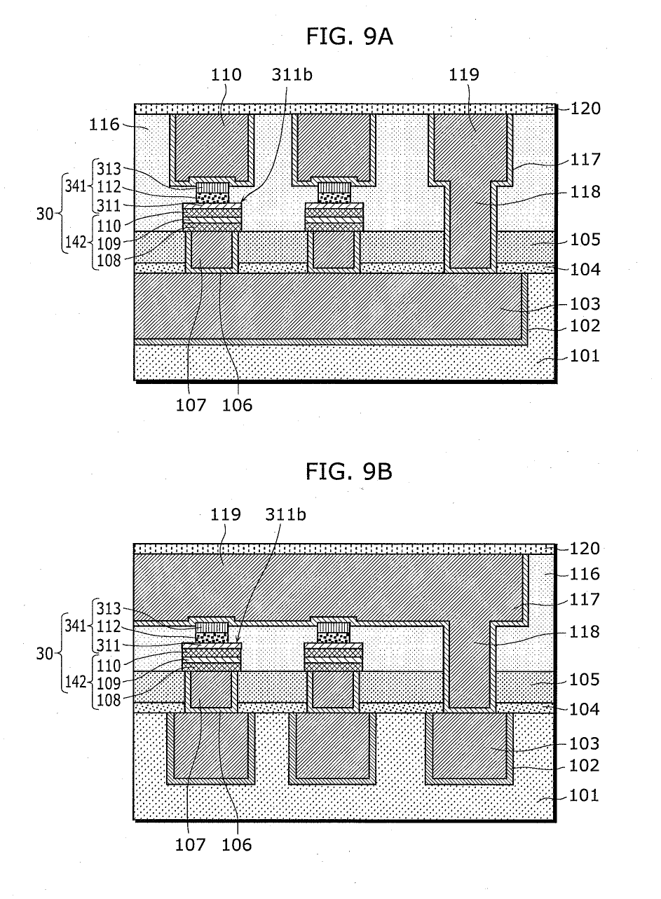

FIGS. 9A and 9B are each a cross-sectional view illustrating a configuration example of the nonvolatile memory element according to Embodiment 3 of the present invention. Similar components to those in FIGS. 2A and 2B are labeled with the same reference symbols, and detailed description is omitted. The plan view illustrating the configuration example of the nonvolatile memory element 30 is similar to FIG. 1. That is to say, FIG. 9A corresponds to the cross-sectional view, as seen in an arrow direction, taken along the chain line indicated by A-A′ in FIG. 1, and FIG. 9B corresponds to the cross-sectional view, as seen in an arrow direction, taken along the chain line indicated by B-B′ in FIG. 1.

The nonvolatile memory element 30 illustrated in FIGS. 9A and 9B differs from the nonvolatile memory element 10 illustrated in FIGS. 2A and 2B in the configuration of the variable resistance element 341. Hereinafter, the details will be described.

The variable resistance element 341 includes the second lower electrode layer 311, the variable resistance layer 112, and the second upper electrode layer 313, which is also the case in the previously described Embodiment 1 and Embodiment 2.

In the present embodiment, the second lower electrode layer 311 comprises a material having an etching rate lower than the etching rate of the second upper electrode layer 313 and the variable resistance layer 112, i.e., comprises, for example, platinum, iridium, or palladium. The dimension of the second lower electrode layer 311 is greater than the dimensions (widths) of the variable resistance layer 112 and the second upper electrode layer 313, and is the same as the dimension (width) of the first upper electrode layer 110 of the current steering element 142.

The second lower electrode layer 311 only needs to have a lower etching rate than the etching rates of the second upper electrode layer 313 and the variable resistance layer 112, and thus the material for the second lower electrode layer 311 is not limited to the aforementioned materials. Optionally, for example, by adjusting a parameter or the like to be used in etching, the etching rate of the second lower electrode layer 311 may be set to be lower than the etching rates of the second upper electrode layer 313 and the variable resistance layer 112.

The second upper electrode layer 313 comprises a metal oxide such as tantalum nitride, for example. Specifically, the second upper electrode layer 313 comprises a material which can be easily etched, and comprises a material other than a precious metal, such as platinum, iridium, and palladium. The second upper electrode layer 313 together with the variable resistance layer 112 forms a step surface 311b with respect to the second lower electrode layer 311 comprising a precious metal. Here, the step surface 311b is a surface parallel to the substrate, and has the area according to at least the width difference between the variable resistance layer 112 of the variable resistance element 341 and the current steering element 142. The step surface 311b is specifically a surface having an area according to the width difference between the second lower electrode layer 311, and the variable resistance layer 112 and the second upper electrode layer 313, however, the step surface 311b is essential a surface having an area according to the width difference between the variable resistance layer 112 of the variable resistance element 341 and the current steering element 142 as described above. Hereinafter, the characteristics in the variable resistance element 341 and the current steering element 142 will be described with reference to the drawings.

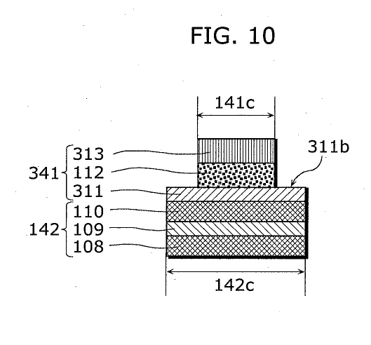

FIG. 10 is a cross-sectional view of a variable resistance element and a current steering element which are included in the nonvolatile memory element according to Embodiment 3 of the present invention. Similar components to those in FIG. 3 are labeled with the same reference symbols, and detailed description is omitted.

The variable resistance element 141 includes the second lower electrode layer 311, the variable resistance layer 112, and the second upper electrode layer 313. The dimension (width) of the second lower electrode layer 311 is greater than the dimensions (widths) of the variable resistance layer 112 and the second upper electrode layer 313, and is the same as the dimension (width) of the first upper electrode layer 110 of the current steering element 142.

As illustrated in FIG. 10, the current steering element width 142c is formed to be greater than the variable resistance element width 141c. In other words, the width (area) of the variable resistance element 341 at least in a direction parallel to a layer in the variable resistance layer 112 is smaller than the width (area) of the current steering element 142 in a direction parallel to the layers in the current steering element 142. As illustrated in FIG. 10, the current steering element 142 has the step surface 311b. Here, similarly to Embodiment 1 or Embodiment 2, the nonvolatile memory element is formed by the below-described characteristic manufacturing method of the present invention. In contrast to the variable resistance element 151 and the current steering element 152 which are illustrated in FIG. 4, the variable resistance element 141 and the current steering element 142 illustrated in FIG. 10 which are formed by the above-described manufacturing method maintain respective interface states stably, and can have an increased width dimension difference between the variable resistance element width 141c of the variable resistance element 341, and the current steering element width 142c of the current steering element 142.

With the nonvolatile memory element 30 having the above configuration, by setting the current steering element width 142c (area of the current steering element 142) of the current steering element 142 to be greater than the variable resistance element width 141c (area of the variable resistance element 341) of the variable resistance element 341, the allowable current of the current steering element 142 can be increased as described in Embodiment 1 with reference to FIG. 12, and thus current control breakdown due to an initial breakdown of the variable resistance element 341 can be prevented.

The first upper electrode layer 110 and the second lower electrode layer 311 may comprise the same material, and thus the variable resistance element 341 and the current steering element 142 may share the same electrode as the electrodes thereof. That is to say, the shared electrode serves as the first upper electrode layer 110 included in the current steering element 142 as well as the second lower electrode layer 311 included in the variable resistance element 341.

Next, a method of manufacturing the aforementioned nonvolatile memory element 30 will be described.

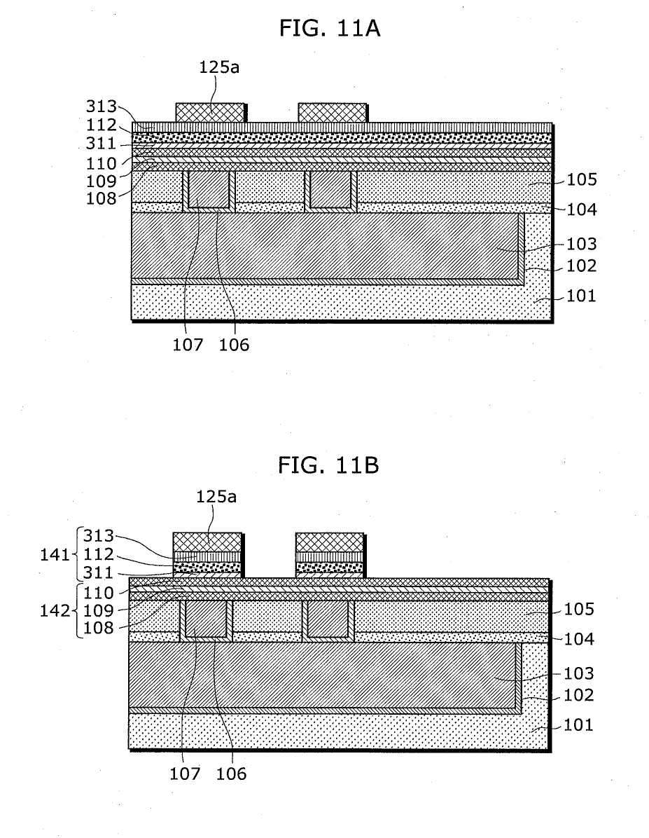

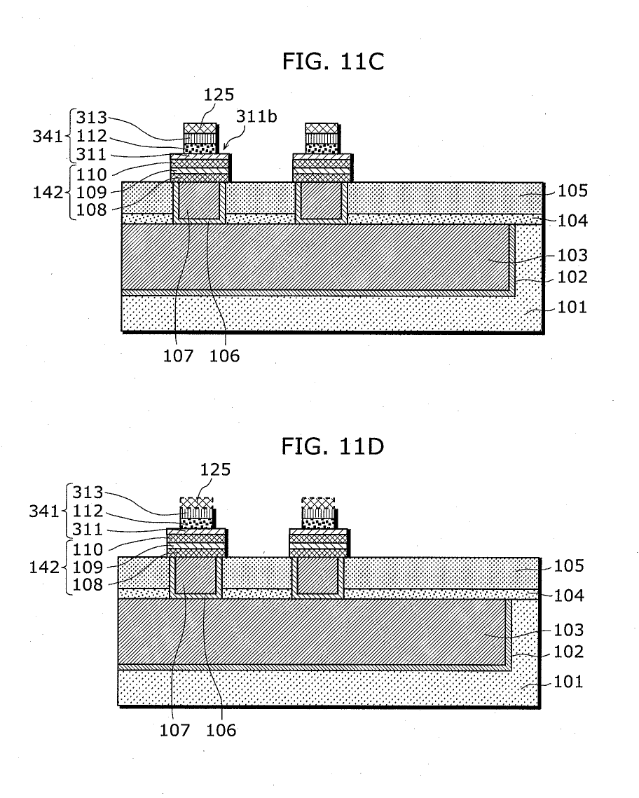

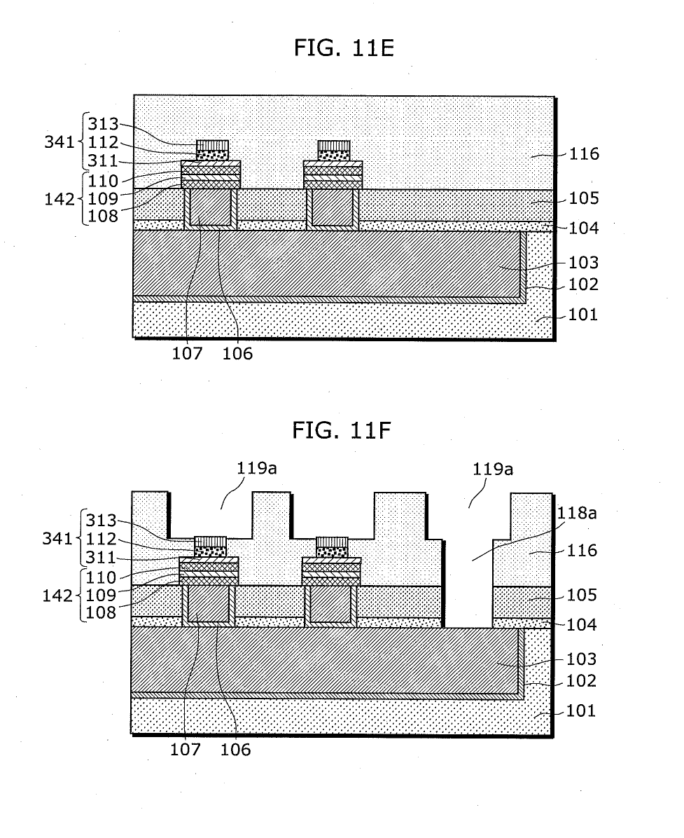

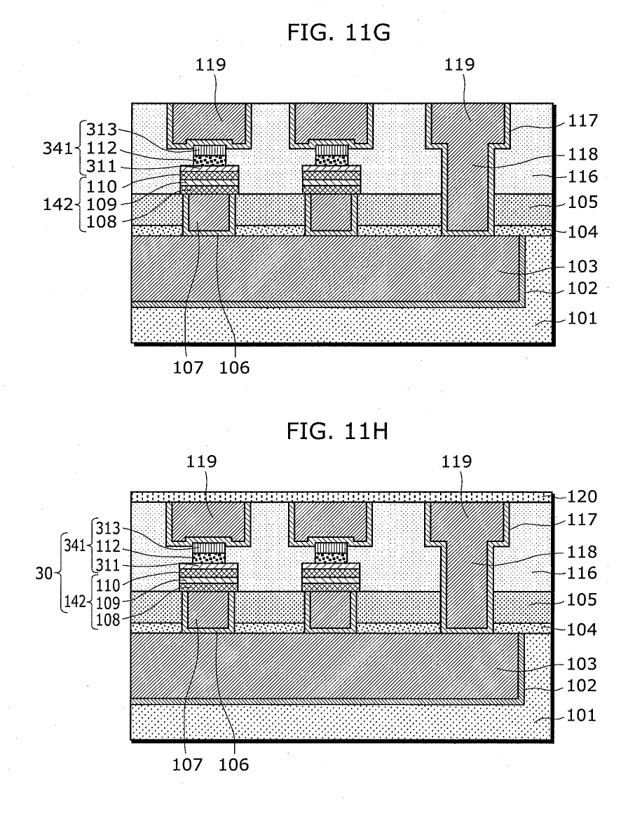

FIGS. 11A to 11H are each a cross-sectional view illustrating a method of manufacturing the nonvolatile memory element 30 according to Embodiment 3 of the present invention. Hereinafter, for the sake of simplicity of the drawing, the case is illustrated where only two pieces of a variable resistance element and a current steering element are formed. FIGS. 11A to 11H illustrate cross-sectional views of the steps which are different from the method of manufacturing the nonvolatile memory element 10 in Embodiment 1. Similar components to those in FIGS. 5A to 5K, FIGS. 6A, 6B, and 7 are labeled with the same reference symbols, and detailed description thereof is omitted.

First, as illustrated in FIG. 11A, the steps illustrated in FIG. 5A and described in Embodiment 1 are performed, and the first lower electrode layer 108, the current steering layer 109, the first upper electrode layer 110, the second lower electrode layer 311, the variable resistance layer 112, and the second upper electrode layer 313 are stacked in this order on the second interlayer insulating layer 105 including the plug 107 by using the manufacturing method similar to the step illustrated in FIG. 5B. Subsequently, the first mask pattern 330 for forming the variable resistance element 341 is formed using photolithography. Here, the first mask pattern 330 is a photoresist mask pattern having a side of 500 nm, for example. Subsequently, a hard mask layer 125a is patterned using the first mask pattern 330 on which photolithography has been performed. Here, the hard mask layer 125a is formed to have a side of 500 nm, for example.

Next, as illustrated in FIG. 11B, the second upper electrode layer 313 included in the variable resistance element 341, the variable resistance layer 112, and the second lower electrode layer 311 comprising a precious metal are patterned by dry etching using, as a mask, the hard mask layer 125a which has been formed using the first mask pattern 330.

Here, the second lower electrode layer 311 comprises iridium, for example, which is a precious metal. The second lower electrode layer 311 is dry etched using a mixed gas of argon, chlorine, and oxygen. In this case, the etching rate of the second lower electrode layer 311 composing iridium is 7.5 times the etching rate of the hard mask layer 125a comprising titanium aluminum nitride. That is to say, the hard mask layer 125a comprising titanium aluminum nitride can serve as a mask without shrinking the thickness and the width, and thus the second upper electrode layer 313, the variable resistance layer 112, and the second lower electrode layer 311 can be patterned. Consequently, the dimension width of the second lower electrode layer 311 becomes the dimension width of the hard mask layer 125a, i.e., 500 nm which is the dimension width of the first mask pattern 330.

As described above, the second lower electrode layer 311 only needs to have a lower etching rate than the etching rates of the second upper electrode layer 313 and the variable resistance layer 112, and thus the material for the second lower electrode layer 311 is not limited to the aforementioned materials. Optionally, for example, by adjusting a parameter or the like to be used in etching, the etching rate of the second lower electrode layer 311 may be set to be lower than the etching rates of the second upper electrode layer 313 and the variable resistance layer 112.

Next, as illustrated in FIG. 11C, the first upper electrode layer 110, the current steering layer 109, and the first lower electrode layer 108 which are included in the current steering element 142 are patterned using dry etching. The dry etching is performed using an etching gas (for example, fluorine sulfide) including a fluorine compound.

When an etching gas (for example, fluorine sulfide) including a fluorine compound is used, the etching rate of titanium aluminum nitride is approximately 2.3 times the etching rate of iridium. The etching rate of tantalum nitride is approximately 5 times the etching rate of iridium, and the etching rate of tantalum oxide is approximately 4.4 times the etching rate of iridium. The first lower electrode layer 108 and the first upper electrode layer 110 comprise, for example, tantalum nitride, and the current steering layer 109 comprises, for example, nitrogen-deficient silicon nitride.

That is to say, when an etching gas (for example, fluorine sulfide) including a fluorine compound is used, etching (dry etching) can be performed using an etching method in which the etching rate of the second lower electrode layer 311 is slower than at least the etching rate of the variable resistance layer 112. Therefore, the second lower electrode layer 311 comprising iridium can serve as a mask without shrinking the thickness and the width due to dry etching, and thus the first upper electrode layer 110, the current steering layer 109, and the first lower electrode layer 108 can be patterned.

Thus, the current steering element width 142c of the current steering element 142 including the first lower electrode layer 108, the current steering layer 109, and the first upper electrode layer 110 can be adjusted to 500 nm. On the other hand, the hard mask layer 125a, the second upper electrode layer 313, and the variable resistance layer 112 shrink in width by the dry etching, and after the current steering element 142 is patterned, the variable resistance element width 141c of the variable resistance element 341, specifically a portion of the variable resistance layer 112 that is in contact with the second lower electrode layer 311 has a width of 200 nm.

In order to shrink the variable resistance element width 141c more than the current steering element width 142c, the hard mask layer 125a at the time of dry etching is desirably to be tapered shape in addition to that the etching rate of the second lower electrode layer 311 is desirably to be lower than those of the second upper electrode layer 313 and the variable-resistance layer 112. Here, tapered shape means that the area of the upper surface of the hard mask layer 125a is lower than the area of the lower surface thereof.

When the hard mask layer 125a is formed in a tapered shape by dry etching, presumably, an etching gas is likely to move around the second upper electrode layer 313 and the variable resistance layer 112. Thus, the second upper electrode layer 313 and the variable resistance layer 112 are presumably more likely to be etched, and the variable resistance element width c becomes smaller than the current suppressing element width 142c. Consequently, the second upper electrode layer 313 and the variable resistance layer 112 are likely to be patterned so as to have a smaller area than the area of the current steering element when viewed in a direction perpendicular to the major surface of the substrate.

Now, a different point from Embodiment 1 is that the current steering element 142 is patterned using the second lower electrode layer 311 as a mask without using the second mask pattern. Because the second mask pattern 131 does not need to be used as stated above, the effect is achieved that the variable resistance element 341 and the current steering element 142 can be reliably formed in series in concentric circular shape regardless of mask alignment precision.

Similarly, in the present embodiment, the current density necessary for an initial breakdown of the variable resistance element 341 is 600 kA/cm², the variable resistance element 141 being manufactured in the above-described manner using tantalum oxide having a thickness of 50 nm for the variable resistance layer 112, and using iridium for the second lower electrode layer 311. On the other hand, the breakdown current density of the current steering element 142 manufactured in the above-described manner is 110 kA/cm². Therefore, in the case where the variable resistance element width 141c of the variable resistance element 341 and the current steering element width 142c of the current steering element 142 are the same width, the current steering element 142 breaks down when a current necessary for an initial breakdown of the variable resistance element 141 is applied to the current steering element 142.

Now, in the present embodiment, similarly to Embodiment 1, the element width (the variable resistance element width 141c) of the variable resistance element is formed to be smaller than the element width (the current steering element width 142c) of the current steering element, so that the current steering element 142 does not break down even when a current (including the current at the time of an initial breakdown) necessary for a resistance change is applied to the variable resistance element 341 (see FIG. 10). Specific examples of the dimensions of the variable resistance element 141, and the dimensions of the current steering element 142 are similar to those in the examples related to, for example, FIG. 12 of Embodiment 1. Therefore, description is omitted.

Next, as illustrated in FIG. 11D, the hard mask layer 125 is removed by etching. It is to be noted that the hard mask layer 125 does not need to be removed and may be left as needed.

Next, as illustrated in FIGS. 11E to 11H, the third interlayer insulating layer 116 is formed so as to cover the variable resistance element 341 and the current steering element 142, and the second wiring 119 connected to the second upper electrode layer 313 is formed on the variable resistance element 341 and the current steering element 142 in the formed third interlayer insulating layer 116. Because these steps are similar to those illustrated in the above-described FIGS. 5H to 5K, description is omitted.

The first upper electrode layer 110 and the second lower electrode layer 311 may comprise the same material, and thus the variable resistance element 141 and the current steering element 142 may share the same electrode as the electrodes thereof. The shared electrode serves as the first upper electrode layer 110 included in the current steering element 142 as well as the second lower electrode layer 111 included in the variable resistance element 141. The step of forming the first upper electrode layer 110 and the step of forming the second lower electrode layer 311 on the first upper electrode layer 110 may be the same step (continuous step).

As described above, with the manufacturing method of the present embodiment, not only the effective area of the current steering element can be made larger than the area of operation of the variable resistance element using a single mask pattern without adding a particular step, but also the variable resistance element and the current steering element can be formed in series in symmetrical concentric circular shape when viewed from above the upper surface of the substrate. Consequently, the effect is achieved that it is possible to easily manufacture a nonvolatile memory element in which even when a current steering element in a conventional configuration is used, a larger amount of current can flow without causing the current steering element to break down, and a necessary and sufficient amount of current for operating the variable resistance element can flow through the variable resistance element.

In addition, with the manufacturing method of the present embodiment, the two elements (the current steering element and the variable resistance element) having different sizes can be formed with a single mask pattern, and thus mask alignment accuracy is not necessary. In addition, the elements can be manufactured with a single mask pattern, thus the number of masks can be decreased, and the costs can be reduced.

In addition, with the manufacturing method of the present embodiment, a current steering element is formed by causing the second lower electrode layer of the variable resistance element to serve as a mask, and the variable resistance element can be formed by shrinking a variable resistance layer included in the variable resistance element, and the end face (the width of the layers in the direction parallel to the layers) of the second upper electrode. Furthermore, because the effective area of the variable resistance element can be adjusted with the etching rate at the time of etching (degree of shrinking), the effect is achieved that a fine pattern, which is difficult to be implemented with a mask pattern, can be formed. Therefore, the effect is achieved that the nonvolatile memory device is compatible with advanced semiconductor miniaturization processes, and thus can be manufactured using semiconductor processes. That is to say, the nonvolatile memory device can be manufactured by a semiconductor process using the conventional CMOS process or the like, and thus a specific and special semiconductor process does not need to be used in manufacturing the variable resistance element and the current steering element, thereby achieving the effect that the variable resistance element can be manufactured with improved compatibility with advanced semiconductor miniaturization processes.

In the above, the embodiments of the present invention have been described. However, the present invention is not limited to the above-described embodiments, and various improvements, changes, and modifications may be made in a range without departing from the gist of the present invention. For example, components in a plurality of the above embodiments may be combined in any manner. In the embodiments, the configuration has been described, in which the plug is disposed only below the variable resistance element and the current steering element. However, the present invention may be applied to a configuration in which a plug is disposed above the elements, or a configuration in which plugs are disposed above and below the elements (a configuration in which the variable resistance element and the current steering element are disposed between the upper and lower plugs), and yet an effect similar to that of the above-described embodiments is achieved.

### INDUSTRIAL APPLICABILITY

The present invention may be utilized in a nonvolatile memory element and a method of manufacturing the nonvolatile memory element, and particularly, in various electronic devices such as digital home appliances, memory cards, mobile telephones, and personal computers.

### REFERENCE SIGNS LIST

1 Memory Cell Array
10, 20, 30 Nonvolatile memory element
101 First interlayer insulating layer
102 First barrier metal layer
103 First wiring
104 First liner layer
105 Second interlayer insulating layer
106 Second barrier metal layer
107 Plug
108, 158 First lower electrode layer
109, 159 Current control layer
110, 160 First upper electrode layer
110b, 311b Step surface
111, 161, 311 Second lower electrode layer
112, 162 Variable resistance layer
113, 163, 313 Second upper electrode layer
116 Third interlayer insulating layer
117 Third barrier metal layer
118 Drawing contact
118a Contact hole
119 Second wiring
119a Line groove
120 Second liner layer
125, 125a Hard mask layer
130, 330 First mask pattern
131 Second mask pattern
141, 151, 341 Variable resistance element
141a, 141b, 141c, 141d Variable resistance element width
141e Lower electrode width of variable resistance element
142, 152 Current control element
142a, 142b, 142c, 142d Current control element width
225 Sidewall layer
225a Insulating layer

1. A method of manufacturing a nonvolatile memory element which includes a current steering element and a variable resistance element, the method comprising:
forming a first lower electrode layer on a substrate;
forming a current steering layer on the first lower electrode layer;
forming a first upper electrode layer on the current steering layer;
forming a second lower electrode layer on the first upper electrode layer;
forming a variable resistance layer comprising a metal oxide on the second lower electrode layer;
forming a second upper electrode layer on the variable resistance layer;
forming a mask on the second upper electrode layer, and patterning the second upper electrode layer, the variable resistance layer, and the second lower electrode layer; and
forming the current steering element including the first lower electrode layer, the current steering layer, and the first upper electrode layer by patterning layers lower than the second lower electrode layer by use of etching which is performed on the second lower electrode layer at an etching rate lower than at least etching rates at which the second upper electrode layer and the variable resistance layer are respectively etched, and forming the variable resistance element including the second upper electrode layer, the variable resistance layer, and the second upper electrode layer, the second upper electrode layer and the variable resistance layer each having an area which is reduced to cause part of an upper surface of the second lower electrode layer to be exposed, the area being as seen in a direction perpendicular to a major surface of the substrate.

2. The method of manufacturing a nonvolatile memory element according to claim 1,
wherein the mask has a tapered shape in the forming of the variable resistance element.

3. The method of manufacturing a nonvolatile memory element according to claim 1,
wherein the layers lower than the second lower electrode layer are the first upper electrode layer, the current steering layer, and the first lower electrode layer.

4. The method of manufacturing a nonvolatile memory element according to claim 1,
wherein the second lower electrode layer and the first upper electrode layer comprise a same material and have a common layer,
the forming of the first upper electrode layer and the forming of the second lower electrode layer are a same forming, and
the layers lower than the second lower electrode layer are the current steering layer and the first lower electrode layer.

5. The method of manufacturing a nonvolatile memory element according to claim 1,
wherein the second lower electrode layer comprises a precious metal including iridium, platinum, or palladium.

6. The method of manufacturing a nonvolatile memory element according to claim 1,
wherein the variable resistance layer has a stacked structure including a first oxygen-deficient transition metal oxide layer and
a second transition metal oxide layer having a degree of oxygen deficiency lower than a degree of oxygen deficiency of the first oxygen-deficient transition metal oxide layer, and
the second transition metal oxide layer is in contact with the second lower electrode layer.

7. The method of manufacturing a nonvolatile memory element according to claim 6,
wherein a resistance value of the second transition metal oxide layer is higher than a resistance value of the first transition metal oxide layer.

8. The method of manufacturing a nonvolatile memory element according to claim 6,
wherein a standard electrode potential of a first transition metal comprised in the first transition metal oxide layer is
higher than a standard electrode potential of the first transition metal comprised in the second transition metal oxide layer.

9. The method of manufacturing a nonvolatile memory element according to claim 1,
wherein the variable resistance layer comprises a tantalum oxide TaOₓ (0<x<2.5), a hafnium oxide HfOₓ (0<x<2.0), or a zirconium oxide ZrOₓ (0<x<2.0).

10. A method of manufacturing a nonvolatile memory element which includes a current steering element and a variable resistance element, the method comprising:
forming a first lower electrode layer on a substrate;
forming a current steering layer on the first lower electrode layer;
forming a first upper electrode layer on the current steering layer;
forming a second lower electrode layer on the first upper electrode layer;
forming a variable resistance layer comprising a metal oxide on the second lower electrode layer;
forming a second upper electrode layer on the variable resistance layer;
forming the variable resistance element including the second lower electrode layer, the variable resistance layer, and the second upper electrode layer by forming a first mask on the second upper electrode layer and patterning the second lower electrode layer, the variable resistance layer, and the second upper electrode layer;
forming an insulating layer which covers the first upper electrode layer and the variable resistance element;
forming a sidewall including an insulating layer on lateral surfaces of the second lower electrode layer, the variable resistance layer, and the second upper electrode layer by etching the insulating layer with an anisotropic etching method; and
forming the current steering element including the first lower electrode layer, the current steering layer, and the first upper electrode layer by patterning the first lower electrode layer, the current steering layer, and the first upper electrode layer using an region surrounded by the sidewall and the first mask or the second upper electrode layer as a second mask.

11. The method of manufacturing a nonvolatile memory element according to claim 10,
wherein the second lower electrode layer and the first upper electrode layer comprise a same material and have a common layer, the forming of the first upper electrode layer, and the forming of the second lower electrode layer on the first upper electrode layer are same,
part of the common layer is patterned in the forming of the variable resistance element, and
the sidewall is formed on a lateral surface of the patterned part of the common layer and on lateral surfaces of the variable resistance layer and the second upper electrode layer in the forming of the sidewall.

12. The method of manufacturing a nonvolatile memory element according to claim 10,
wherein at least one of the second upper electrode layer and the second lower electrode layer comprises a precious metal including iridium, platinum, and palladium.

13. The method of manufacturing a nonvolatile memory element according to claim 10,
wherein the variable resistance layer has a stacked structure including a first oxygen-deficient transition metal oxide layer and
a second transition metal oxide layer having a degree of oxygen deficiency lower than a degree of oxygen deficiency of the first oxygen-deficient transition metal oxide layer, and
the second transition metal oxide layer is in contact with the second lower electrode layer.

14. The method of manufacturing a nonvolatile memory element according to claim 13,
wherein a resistance value of the second transition metal oxide layer is higher than a resistance value of the first transition metal oxide layer.

15. The method of manufacturing a nonvolatile memory element according to claim 10,
wherein a standard electrode potential of the first transition metal comprised in the first transition metal oxide layer is
higher than a standard electrode potential of the first transition metal comprised in the second transition metal oxide layer.

16. The method of manufacturing a nonvolatile memory element according to claim 10,
wherein the variable resistance layer comprises a tantalum oxide TaOₓ (0<x<2.5), a hafnium oxide HfOₓ (0<x<2.0), or a zirconium oxide ZrOₓ (0<x<2.0).

17. A method of manufacturing a nonvolatile memory element which includes a current steering element and a variable resistance element, the method comprising:
forming a first lower electrode layer on a substrate;
forming a current steering layer on the first lower electrode layer;
forming a first upper electrode layer on the current steering layer;
forming a second lower electrode layer on the first upper electrode layer;
forming a variable resistance layer comprising a metal oxide on the second lower electrode layer;
forming a second upper electrode layer on the variable resistance layer;
forming the variable resistance element including the second lower electrode layer, the variable resistance layer, and the second upper electrode layer by forming a first mask and patterning at least the variable resistance layer and the second upper electrode layer;
forming a second mask which is larger than the first mask and covers at least the first mask, the variable resistance layer, and the second upper electrode layer; and
forming the current steering element including the first lower electrode layer, the current steering layer, and the first upper electrode layer by patterning the first lower electrode layer, the current steering layer, and the first upper electrode layer using the formed second mask.

18. The method of manufacturing a nonvolatile memory element according to claim 17,
wherein the second lower electrode layer and the first upper electrode layer comprise a same material and have a common layer, and
the forming of the first upper electrode layer and the forming of the second lower electrode layer on the first upper electrode layer are same.

19. The method of manufacturing a nonvolatile memory element according to claim 17,
wherein at least one of the second upper electrode layer and the second lower electrode layer comprises iridium, platinum, or palladium.

20. The method of manufacturing a nonvolatile memory element according to claim 17,
wherein the variable resistance layer has a stacked structure including a first oxygen-deficient transition metal oxide layer, and
a second transition metal oxide layer having a degree of oxygen deficiency lower than a degree of oxygen deficiency of the first oxygen-deficient transition metal oxide layer, and
the second transition metal oxide layer is in contact with the second lower electrode layer.

21. The method of manufacturing a nonvolatile memory element according to claim 20,
wherein a resistance value of the second transition metal oxide layer is higher than a resistance value of the first transition metal oxide layer.

22. The method of manufacturing a nonvolatile memory element according to claim 20,
wherein a standard electrode potential of the first transition metal comprised in the first transition metal oxide layer is
higher than a standard electrode potential of the first transition metal comprised in the second transition metal oxide layer.

23. The method of manufacturing a nonvolatile memory element according to claim 17,
wherein the metal oxide is a tantalum oxide TaOₓ (0<x<2.5), a hafnium oxide HfOₓ (0<x<2.0), or a zirconium oxide ZrOₓ (0<x<2.0).

24. A nonvolatile memory element comprising a variable resistance element and a current steering element which are connected in series,
the current steering element including:
a first lower electrode layer formed on a substrate;
a current steering layer formed on the first lower electrode layer; and
a first upper electrode layer formed on the current steering layer,
the variable resistance element including:
a second lower electrode layer formed on the first upper electrode layer;
a variable resistance layer comprising a metal oxide and formed on the second lower electrode layer;
a second upper electrode layer formed on the variable resistance layer; and
a sidewall including an insulating layer, the sidewall being formed on lateral surfaces of the second lower electrode layer, the variable resistance layer, and the second upper electrode layer,
wherein a width of the current steering element in a direction parallel to each layer included in the current steering element is greater than a width of the variable resistance layer in a direction parallel to a layer included in at least the variable resistance layer in the variable resistance element, and
the current steering element has a step surface which is parallel to the substrate and is a surface having an area according to at least a width difference between the variable resistance layer in the variable resistance element and the current steering element.

25. The nonvolatile memory element according to claim 24,
wherein the second lower electrode layer and the first upper electrode layer comprise a same material.

26. (canceled)

27. The nonvolatile memory element according to claim 24,
wherein at least one of the second upper electrode layer and the second lower electrode layer comprises iridium, platinum, or palladium.

28. The nonvolatile memory element according to claim 24,
wherein the metal oxide comprises a tantalum oxide TaOₓ (0<x<2.5), a hafnium oxide HfOₓ (0<x<2.0), or a zirconium oxide ZrOₓ (0<x<2.0).
